(19) United States
(12) Patent Application Publication
(10) Pub. No.: US 2013/0307054 A1
(43) Pub. Date: Nov. 21, 2013

(54) SEMICONDUCTOR INTEGRATED CIRCUIT

(71) Applicants: Shinichi YASUDA, Tokyo (JP); Kosuke Tatsumura, Kawasaki-shi (JP); Mari Matsumoto, Yokohama-shi (JP); Koichiro Zaitsu, Kawasaki-shi (JP); Masato Oda, Yokohama-shi (JP); Atsuhiro Kinoshita, Kamakura-shi (JP); Daisuke Hagishima, Kawasaki-shi (JP); Yoshifumi Nishi, Niigata-shi (JP); Takahiro Kurita, Kawasaki-shi (JP); Shinobu Fujita, Tokyo (JP)

(72) Inventors: Shinichi YASUDA, Tokyo (JP); Kosuke Tatsumura, Kawasaki-shi (JP); Mari Matsumoto, Yokohama-shi (JP); Koichiro Zaitsu, Kawasaki-shi (JP); Masato Oda, Yokohama-shi (JP); Atsuhiro Kinoshita, Kamakura-shi (JP); Daisuke Hagishima, Kawasaki-shi (JP); Yoshifumi Nishi, Niigata-shi (JP); Takahiro Kurita, Kawasaki-shi (JP); Shinobu Fujita, Tokyo (JP)

(21) Appl. No.: 13/606,292

(22) Filed: Sep. 7, 2012

(30) Foreign Application Priority Data
May 15, 2012 (JP) 2012-111974

(51) Int. Cl. H01L 27/105

(52) U.S. Cl. 257/326; 257/E27.081

(57) ABSTRACT

One embodiment provides a semiconductor integrated circuit, including: a substrate; a plurality of nonvolatile memory portions formed in the substrate, each including a first nonvolatile memory and a second nonvolatile memory; and a plurality of logic transistor portions formed in the substrate, each including at least one of logic transistor, wherein the logic transistors include: a first transistor which is directly connected to drains of the first and second nonvolatile memories at its gate; and a second transistor which is not directly connected to the drains of the first and second nonvolatile memories, and wherein a bottom surface of the gate of each of the logic transistors sandwiching the first and second nonvolatile memories is lower in height from a top surface of the substrate than a bottom surface of the control gate of each of the first and second nonvolatile memories.

### CROSS-REFERENCE TO RELATED APPLICATION(S)

This application claims priority/priorities from Japanese Patent Application No. 2012-111974 filed on May 15, 2012, the entire contents of which are incorporated herein by reference.

### FIELD

Embodiments described herein relate generally to a semiconductor integrated circuit.

### BACKGROUND

In recent years, reconfigurable integrated circuit devices such as field programmable gate arrays (FPGAs) have attracted attention. An FPGA includes logic blocks for implementing basic logic information and switches for changing the interconnection between the logic blocks, thereby allowing the user to realize arbitrary logic functions. Logic information implemented by the logic blocks and connection information of the switches are stored in a configuration memory.

As the configuration memory, a static random access memory (SRAM) type memory is widely used. In SRAM-type memories, leakage current increases as the miniaturization of semiconductor devices proceeds. Thus, in FPGA using such SRAM-type memories, leakage current also increases. In order to reduce power consumption, there is considered, for example, a method of shutting off a power supply when the FPGA is in an unused state. However, since the SRAM-type memory is a volatile memory, when the power supply is shut off, data stored in the SRAM-type memory is lost. Thus, the method can not be applied to the FPGA using the SRAM-type memory.

There is also considered a method of mounting a nonvolatile memory on the chip and transferring data to a retaining circuit for retaining data when FPGA recovers from the power-supply shut-off state. However, in this method, nonvolatile memory areas are collectively provided as a block, and the area of the chip increases. In addition, since SRAM or a flip-flop is used as the retaining circuit, the area of the chip further increases.

### BRIEF DESCRIPTION OF DRAWINGS

FIG. 1 illustrates a cell of a logic switch according to a first embodiment.

FIGS. 2 to 5 illustrate specific examples of the cell.

FIGS. 6A to 8 illustrate a writing method.

FIG. 9 illustrates a relation between a voltage at a node Q in the cell and a voltage applied to a bit line BL2.

FIGS. 10 to 12 illustrate examples of a cell array of the logic switch according to the first embodiment.

FIG. 13 illustrates an erasure method.

FIGS. 14 to 19C illustrate layout examples of a semiconductor integrated circuit having the logic switch.

FIG. 20 illustrates an operation of the cell of the logic switch.

FIGS. 21 to 22 illustrate example structures of a memory transistor of the logic switch.

FIGS. 23A to 24B illustrate manufacturing steps for forming a STI and an insulating film of the memory transistor.

FIGS. 25A to 28 illustrate manufacturing steps for forming an insulating film of a pass transistor.

FIGS. 29A to 34F illustrate manufacturing steps for forming gate structures of the memory transistor and the pass transistor.

FIGS. 35A to 38 illustrate manufacturing steps for wiring.

FIGS. 39A to 39D illustrate an operation of a cell of a logic switch.

FIGS. 40 to 41B illustrate further layout examples of a semiconductor integrated circuit having the logic switch according to the first embodiment.

### DETAILED DESCRIPTION

One embodiment provides a semiconductor integrated circuit, including: a substrate; a plurality of nonvolatile memory portions formed in the substrate, each nonvolatile memory portion including a first nonvolatile memory having a control gate, and a second nonvolatile memory having a control gate connected to the control gate of the second nonvolatile memory; and a plurality of logic transistor portions formed in the substrate, each logic transistor portion including at least one of logic transistor, wherein the logic transistors include: a first transistor which is directly connected to drains of the first and second nonvolatile memories at its gate; and a second transistor which is not directly connected to the drains of the first and second nonvolatile memories, and wherein, among the logic transistors, a bottom surface of the gate of each of the transistors sandwiching the first and second nonvolatile memories is lower in height from a top surface of the substrate than a bottom surface of the control gate of each of the first and second nonvolatile memories.

### First Embodiment

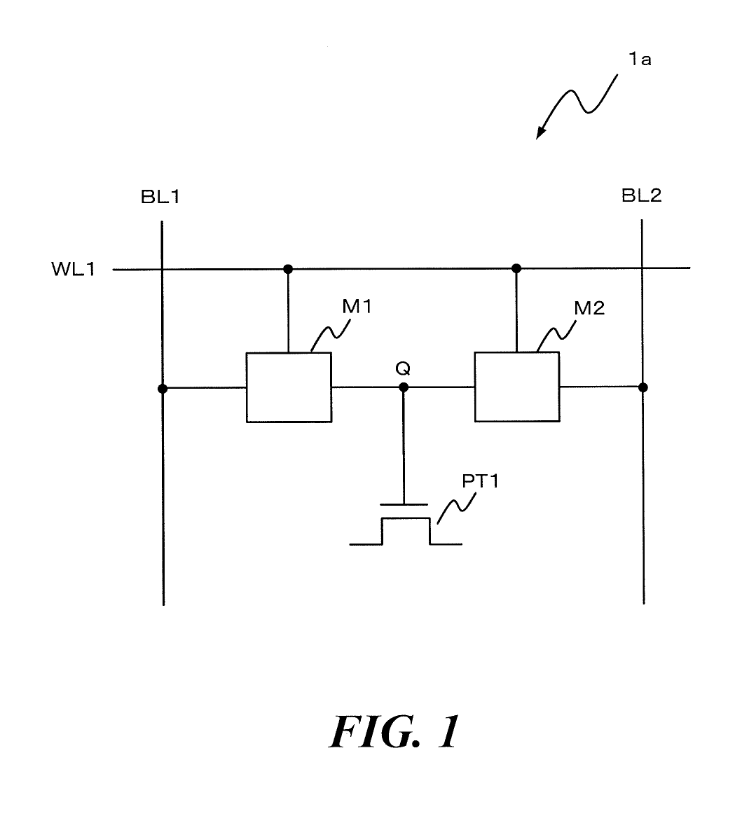

Hereinafter, an embodiment is described with reference to the drawings. FIG. 1 illustrates one cell of a programmable logic switch (logic switch) according to the present embodiment. A cell 1a of the logic switch according to the present embodiment includes two nonvolatile memories M1 and M2 and one pass transistor PT1. Each of the nonvolatile memories M1 and M2 includes a signal electrode and a control electrode and changes a state thereof according to signals respectively input to the signal electrode and the control electrode. Terminals of the nonvolatile memories M1 and M2 are connected to a node Q. The control electrodes the nonvolatile memories M1 and M2 are connected to a word line WL1. In addition, the nonvolatile memory M1 is connected to a bit line BL1. The nonvolatile memory M2 is connected to a bit line BL2. The gate of the pass transistor PT1 is connected to the node Q.

In the cell 1a, data can be written to one of the nonvolatile memories M1 and M2 by adjusting the magnitude of a voltage applied to each of the word line WL1 and the bit lines BL1 and BL2 and the voltage application timing thereto. In addition, data can collectively be erased from the nonvolatile memories M1 and M2. The nonvolatile memories M1 and M2 are, e.g., flash memory transistors or three-terminal nonvolatile microelectromechanical system (MEMS) switches. Hereinafter, a flash memory transistor having a charge storage film is described as an example for each of the nonvolatile memories M1 and M2.

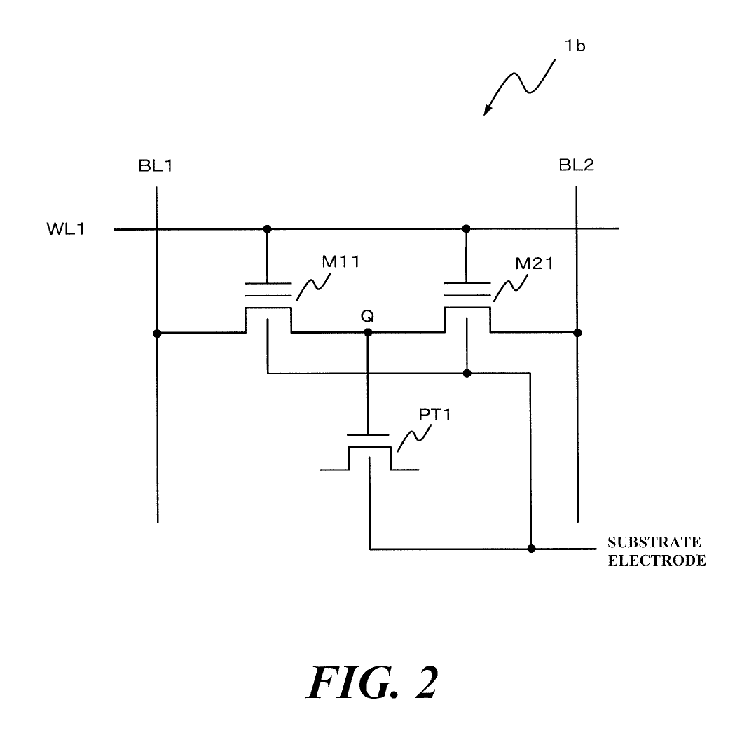

FIG. 2 illustrates a cell 1b which uses a flash memory transistor (memory transistor) as the nonvolatile memories. The cell 1b includes two memory transistors M11 and M21 and one pass transistor PT1.

The memory transistors M11 and M21 may be floating-gate (FG) type transistors using electrically conductive floating gates (e.g., n-doped polysilicon or p-doped polysilicon) as charge storage films. Alternatively, the memory transistors M11 and M21 may be metal-oxide-nitride-oxide-semiconductor (MONOS) type transistors using insulating silicon nitride or oxide films as charge storage films. A structure in which an insulating silicon nitride or oxide film is stacked on an electrically conductive polysilicon may be used. In the case of using the MONOS type transistors as the memory transistors, a manufacturing-process for the logic transistor such as the pass transistor PT1 is compatible with a manufacturing-process for the memory transistors. Thus, the memory transistors can be arranged close to the logic transistor, as compared with the case of using the FG-type transistors as the memory transistors. Accordingly, the area of a chip can be reduced. The following description is made by assuming that the memory transistors M11 and M21 according to the present embodiment are MONOS-type transistors using silicon nitride films as the charge storage films.

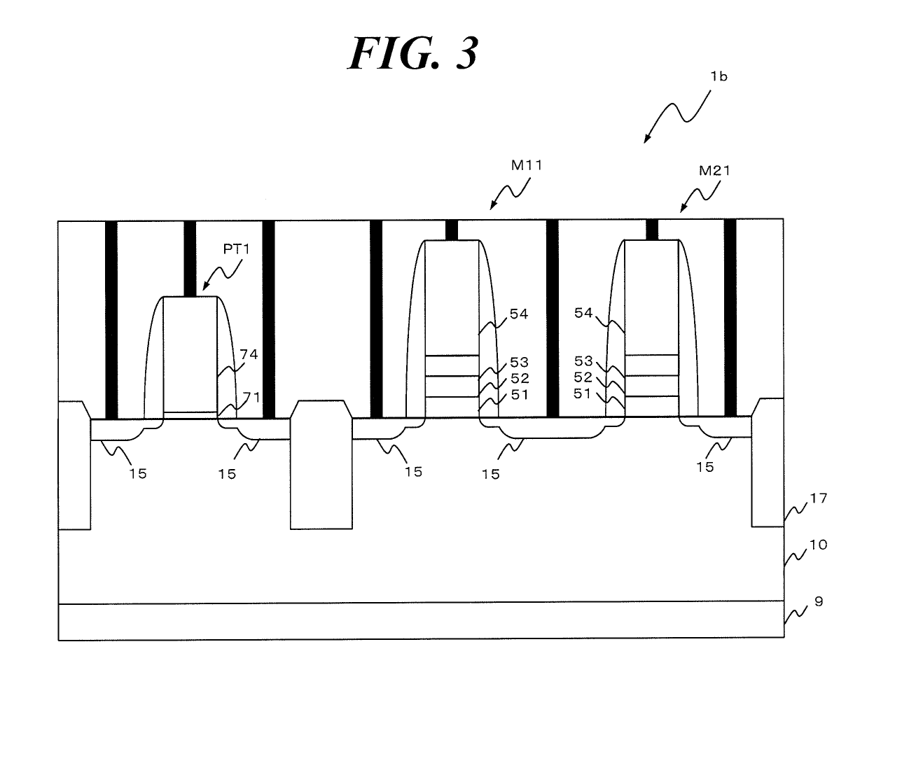

FIG. 3 cross-sectionally illustrates the cell 1b. As illustrated in FIG. 3, the memory transistors M11 and M21 and the pass transistor PT1 are manufactured on the same well 10. A substrate electrode (not shown) for applying a substrate voltage is provided on the well 10. The memory transistors M11 and M21 are MONOS type transistors each having a gate structure in which a silicon oxide film (tunnel film) 51 formed above a channel formation part of a silicon substrate 9, a silicon nitride film (charge storage film) 52 formed above the tunnel film 51, a silicon oxide film (block film) 53 formed above the charge storage film 52 and a gate electrode 54 formed above the block film 53 are stacked.

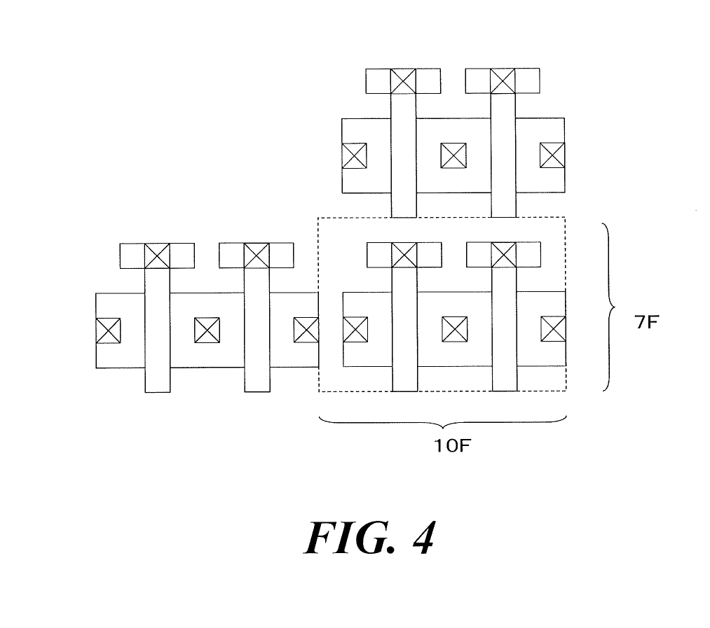

Thus, if all of contacts/vias and the gates of transistors are laid out in terms of an equal distance length F when information of 1 bit is represented using the two memory transistors M11 and M21, the minimum area of each object including a margin with each adjacent cell therefrom is 10F×7F, as illustrated in FIG. 4. Actually, not all objects have the same size. There is slight variation in size with the objects. For example, some transistors are smaller in gate length, while some contacts are larger in thickness. However, assuming that the width in a channel direction of a gate, which is a minimum processing dimension, is F, the actual minimum area of each object has a similar value. On the other hand, the minimum area of SRAMs is, e.g., 120F². If a pass transistor is arranged adjacently in the channel direction of the gate of a memory transistor, the pass transistor and the memory transistor are arranged across a single element isolation region (i.e., a shallow trench isolation (STI) region), whose width is equal to or larger than 1F and smaller than 7F, such that the distance between the pass transistor and the memory transistor is equal to or larger than 1F and smaller than 7F. Consequently, the area of a chip will be smaller than the minimum area (=120F²) of SRAMs. If a pass transistor is arranged adjacently in a channel width direction of the gate of a memory transistor, the pass transistor and the memory transistor are arranged such that the distance between the pass transistor and the memory transistor is equal to or larger than 1F and smaller than 5F. Consequently, the area of a chip will be smaller than the minimum area of SRAMs. Thus, the memory transistor M21 and the pass transistor PT1 adjoin each other across the single element isolation region (STI region) having a width which is equal to or larger than 1F and less than 7F. Accordingly, if the power supply to the logic switch is resumed after the power supply thereto is once interrupted, the on/off of the pass transistor PT1 can quickly be controlled according to data stored in the memory transistors M11 and M21.

As illustrated in FIG. 2, the gates of the memory transistors M11 and M21 are connected to the word line WL1. One of the source/drain electrodes 15 of the memory transistor M11 is connected to the bit line BL1. The other of the source/drain electrodes 15 of the memory transistor M11 is connected to one of the source/drain electrodes of the memory transistor M21. The other of the source/drain electrodes 15 of the memory transistor M21 is connected to the bit line BL2. A connection node Q between the memory transistors M11 and M21 is connected to the gate of the pass transistor PT1.

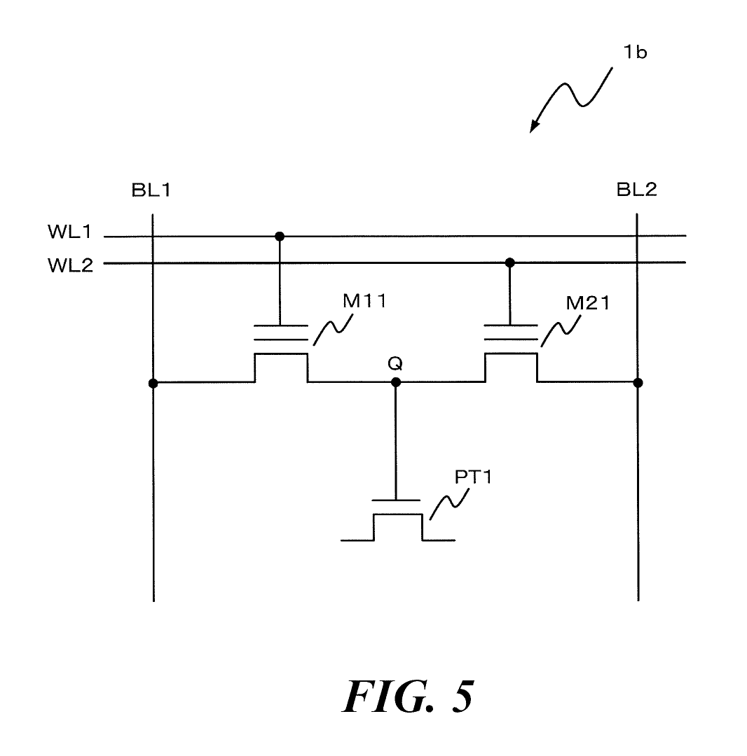

Since the gates of the memory transistors M11 and M21 are connected to the word line WL1, the gates of the memory transistors M11 and M21 are at the same voltage. Even in a case where the gate of the memory transistor M11 and the gate of the memory transistor M21 are locally connected to different wires WL1 and WL2, respectively, as illustrated in FIG. 5, if the wires WL1 and WL2 are operated at the same voltage, such a cell can perform each of all methods, such as a writing method, an erasure method and an operation method, described below, similarly to the cell 1b illustrated in FIG. 2.

The following description is made by assuming that the memory transistors M11 and M21 are N-type transistors formed on a P-type well. However, the memory transistors M11 and M21 may be P-type transistors formed on an N-type well. Although the memory transistors M11 and M21 are formed on the same active area (AA) surrounded by the STI 17, as illustrated in FIG. 3, the memory transistors M11 and M21 may be formed on different AAs. In addition, the following description is made by assuming that the substrate is a silicon substrate. However, other types of semiconductors may be used as the substrate. In addition, each of the tunnel film, the charge storage film, the block film and the gate electrode may be a stack of plural films of different types.

### (Writing Method)

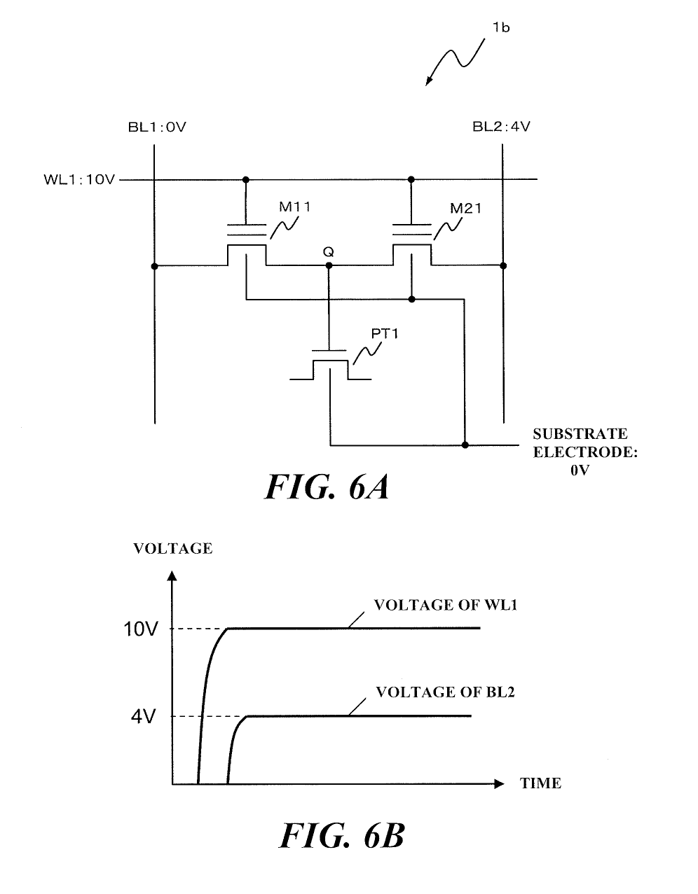

Hereinafter, a writing method for writing data to the memory transistors M11 and M21 of the cell 1b is described with reference to FIGS. 6A to 8. In the following description, a state in which a large amount of electrons is stored in a charge storage film of a memory transistor, so that a threshold voltage Vth is high, is referred to as a written state, and a state in which a small amount of electrons is stored in the charge storage film of the memory transistor, so that the threshold voltage Vth is low, is referred to as an erased state. In addition, the following description is made by assuming that a threshold voltage for the erased state of each of the memory transistors M11 and M21 is 2 volts (V), and that a threshold voltage for the written state of each of the memory transistors M11 and M21 is 6 V.

The write method according to the present embodiment utilizes channel hot electrons (CHEs). CHEs are electrons each having extremely high energy, and such CHEs are generated when the drain voltage of a transistor becomes larger than a certain amount to thereby cause channel pinch-off at the drain end. The CHEs generated due to the voltage difference between the source and the drain of the transistor are drawn into the charge storage film by a gate voltage. Thus, writing data to the memory transistors is accomplished. The writing method using CHEs has an advantage over a writing method using Fowler-Nordheim (FN) current in that a voltage applied to each terminal is small.

In a case where data is written only to the memory transistor M21 when each of the memory transistors M11 and M21 is in an erased state, a control circuit applies a first write voltage and a second write voltage to the word line WL1 and the word line WL2, respectively, as illustrated in FIG. 6A. In addition, the control circuit applies a ground voltage to the bit line BL1 and the substrate electrode.

The first write voltage is set to be equal to or higher than the threshold voltage Vth for the memory transistors M11 and M21 in the erased state, and to be lower than a voltage at which data is written to the memory transistor using FN current. More specifically, a voltage of about 20 V is needed to write data to the memory transistor using FN current. Thus, the first write voltage is set to be lower than 20 V.

The second write voltage is set to be enough to overcome a barrier height between silicon and the tunnel film 51. This is because it is necessary that CHEs generated at the drain end of the memory transistor M21 leap an energy barrier of the silicon oxide film (tunnel film) 51 and go into the silicon nitride film (charge storage film) 12. In addition, the second write voltage is set sufficient not to break the p-n junction formed between a (P-type) well of the memory transistor M21 and an (N-type) source-drain diffusion layer.

In the present embodiment, the first write voltage is set at, e.g., 10 V. The second write voltage is set at, e.g., 4 V. However, the first write voltage and the second write voltage are not limited thereto. The first write voltage and the second write voltage may be the same voltage. The second write voltage may be larger than the first write voltage.

FIG. 6B illustrates application timings of the first write voltage and the second write voltage. In the present embodiment, as illustrated in FIG. 6B, the first write voltage is given to the word line WL1 before the second write voltage is given to the bit line BL2.

In the writing method, data can be selectively written to the memories, while the breakdown of the gate of the pass transistor PT1 due to the write voltage can be avoided. First, a principle for selectively writing data to the memory is described hereinafter.

When the first write voltage (e.g., 10 V) is applied to the word line WL1, both of the memory transistors M11 and M21 are put into an on-state. The first write voltage is lower than a voltage needed to write data to the memory using FN current. Thus, only the application of the first write voltage thereto is not enough to perform the writing of data to one of the memory transistors M11 and M21.

Then, the second write voltage (e.g., 4 V) is applied to the bit line BL2. Consequently, a voltage difference (drive voltage) between the source and the gate is differentiated between the memory transistors M11 and M21. The drive voltage of the memory transistor M11 is 10 V. The drive voltage of the memory transistor M21 is 6 V. Generally, as the drive voltage of a transistor increases, the channel resistance of the transistor decreases. That is, the memory transistor M11 is lower in resistance than the memory transistor M21 connected to the bit line BL2.

Hereinafter, the channel resistance of the memory transistor M11 is designated with “R1”, while the channel resistance of the memory transistor M21 is designated with “R2”. The voltages respectively applied to the bit lines BL1 and BL2 are designated with “VBL1” and “VBL2”. The voltage at the node Q is designated with “VQ”. The voltage VQ is expressed by the following expression.

VQ=(R1/(R1+R2))*(VBL2−VBL1)

Because R1<R2, the voltage VQ is closer to VBL1 than VBL2. The source-drain voltage of the memory transistor M21 is larger than the source-drain voltage of the memory transistor M11.

As described above, CHEs are generated when the channel of a transistor is pinched off at the drain end thereof. If the source-drain voltage of the memory transistor is increased, channel pinch-off occurs when the source-drain voltage thereof reaches a certain voltage (“VDsat”). If channel pinch-off occurs once, the drain current thereof is saturated.

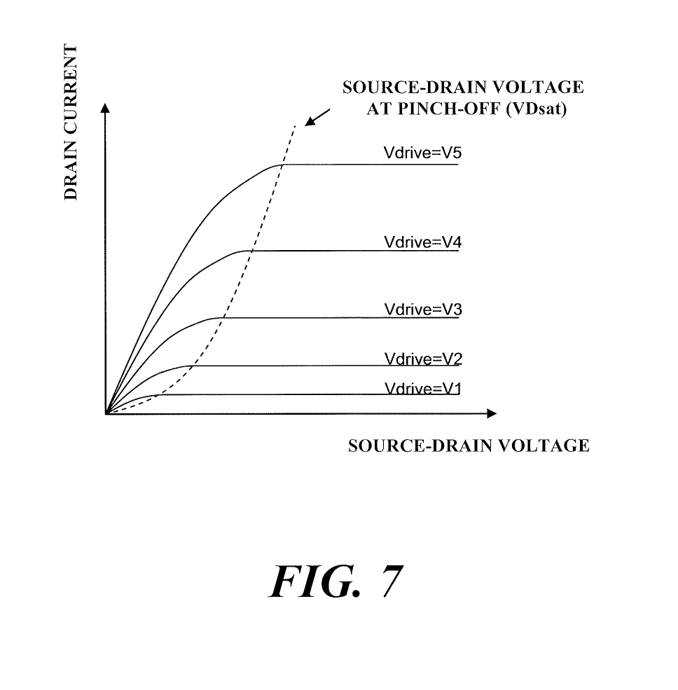

FIG. 7 illustrates the relation between the source-drain voltage and the drain current of a memory transistor in the case of giving five-types of drive voltages (Vdrive) to the memory transistor. The five types of the drive voltages illustrated in FIG. 7 satisfy V1<V2<V3<V4<V5. A dashed curve represents a source-drain voltage (VDsat) when the channel of the transistor is pinched off. Generally, as the drive voltage increases, the source-drain voltage VDsat increases. As described above, the drive voltage of the memory transistor M11 is larger than the drive voltage of the memory transistor M21. That is, a necessary source-drain voltage of a transistor, which is needed to pinch off the channel, of the memory transistor M11 is larger than that of the memory transistor M21. However, the memory transistor M11 is smaller in source-drain voltage than the memory transistor M21. Thus, channel pinch-off occurs in the memory transistor M21, and the writing of data to the memory due to CHEs is performed at the memory transistor M21. Since a necessary source-drain voltage needed to cause channel pinch-off is not obtained at the memory transistor M11, the writing of data to the memory due to CHEs is not caused.

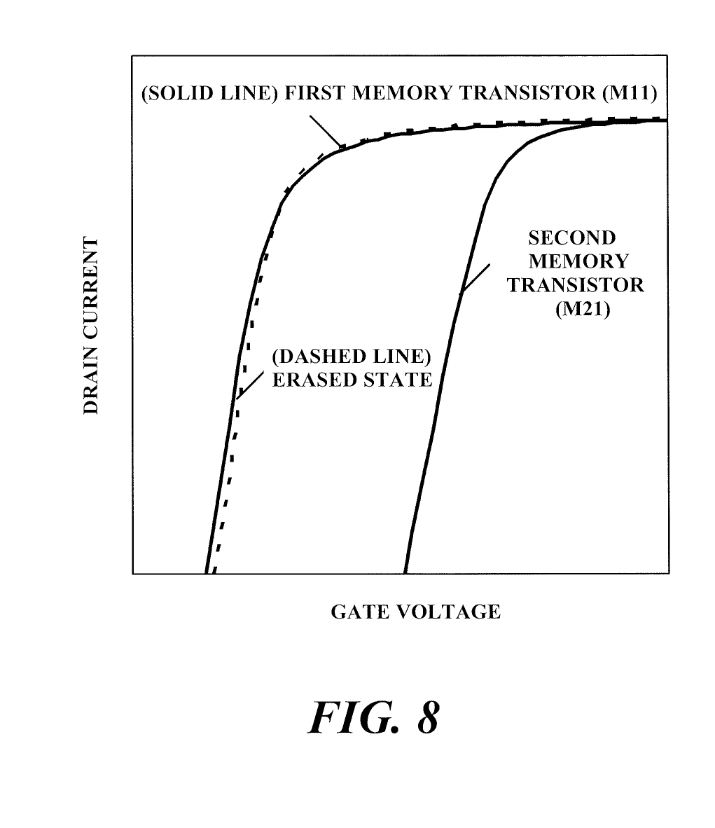

FIG. 8 illustrates experimental result obtained by performing the selective writing of data to the memory transistors with the writing method of the present embodiment on a device having the cell 1b illustrated in FIG. 2. In FIG. 8, a dashed curve represents a characteristic of a memory transistor in an erased state. In the present embodiment, the two memory transistors have the same characteristic. Therefore, in a case where both the two memory transistors are in an erased state, the characteristics of the two memory transistors are the same as each other. In FIG. 8, solid curves represent the characteristics of the two memory transistors in the case of performing the writing method illustrated in FIGS. 6A and 6B on the cell 1b including the two memory transistors that are in an erased state. As illustrated in FIG. 8, if the writing method illustrated in FIGS. 6A and 6B are performed, the threshold voltage Vth for the memory transistor M11 does not change, and only the threshold value Vth for the memory transistor M21 rises. That is, it is indicated that data has been selectively written to the memory transistor M21.

Next, a principle for avoiding the breakdown of the gate of the pass transistor PT1 due to the write voltage is described hereinafter. In order to implement a high-speed logic switch, preferably, the thickness of a gate insulating film of the pass transistor PT1 is several nanometers (nm). The breakdown withstanding voltage of the gate insulating film in this case is considered to be about 2 V. Accordingly, if the voltage at the node Q is equal to or higher than 2 V, the breakdown of the gate of the pass transistor PT1 may occur.

In the writing method of the present embodiment, the memory transistor M11 is larger than the memory transistor M21 in the drive voltage when writing data. Accordingly, the voltage VQ at the node Q is substantially 0 V. Consequently, the cell 1b is stable in a state in which substantially no voltage is applied to the gate of the pass transistor PT1.

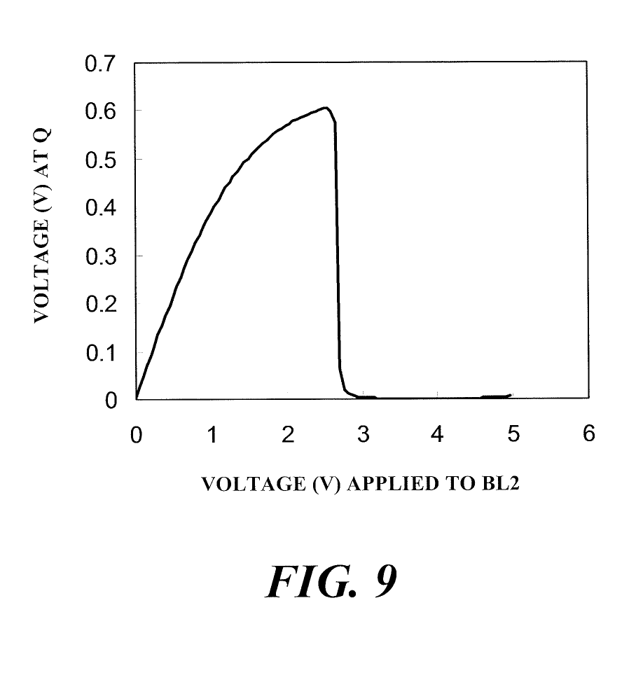

FIG. 9 illustrates the change of the voltage VQ at the node Q, which is caused when the voltage VBL2 applied to the bit line BL2 in a state in which a voltage of 10 V is applied to the word line WL1 of the cell 1b illustrated in FIG. 2. In a range in which the voltage VBL2 is equal to or lower than 1 V, the graph is substantially linear. The gradient of the substantially-straight-line graph is less than 0.5. This means that the channel resistance R1 of the memory transistor M11 is less than the channel resistance R1 of the memory transistor M21. If the voltage VBL2 is increased, the voltage VQ becomes constant to be substantially 0 V at a certain point. This indicates that channel pinch-off occurs at the memory transistor M21, and that data is written to the memory transistor M21 due to CHEs generated at the memory transistor M21 to thereby extremely increase the channel resistance R2 of the memory transistor M21.

Thus, according to the writing method of the present embodiment, the voltage VQ can be suppressed to 0 V or a value close to 0 V, a voltage that may cause breakdown of the pass transistor PT1 (about 2 V) is not applied to the pass transistor PT1. Accordingly, in the cell 1b, the thickness of the gate insulating film of the pass transistor PT1 can be made sufficiently thin. Thus, a high-speed operation of a logic switch can be accomplished.

As illustrated in FIG. 6B, according to the present embodiment, the first write voltage is given to the word line WL1 before the second write voltage is given to the bet line BL2. If the second write voltage is given to the bit line BL2 when the word line WL1 is at a voltage of 0 V or in a floating state, no difference may be caused between the channel resistance R1 of the memory transistor MT1 and the channel resistance R2 of the memory transistor M21. Thus, the voltage VQ may be equal to or higher than the breakdown voltage of the pass transistor. In addition, in a case where a difference in threshold voltage Vth between the memory transistors M11 and M21 in an erased state is caused due to production tolerance and the like, so that the threshold voltage Vth for the memory transistor M21 is less than the threshold voltage Vth for the memory transistor M11, the resistance of the memory transistor M21 is lower than the resistance of the memory transistor M11. At that time, if the second write voltage is given to bit line BL2, the voltage VQ is close to the voltage VBL2 applied to the bit line BL2. Thus, the breakdown of the gate of the pass transistor PT1 may occur.

On the other hand, if the first write voltage is given to the word line WL1 before the second write voltage is given to the bit line BL2, a difference in drive voltage is necessarily caused between the memory transistors M11 and M21 when the second write voltage is given to the bit line BL2. The difference in the drive voltage is sufficiently larger than an amount of variation of the threshold voltage of the memory transistor. Thus, when the second write voltage is given to the bit line BL2, the voltage VQ does not become unexpectedly close to the voltage VBL2. A voltage more than expected is not applied to the pass transistor PT1.

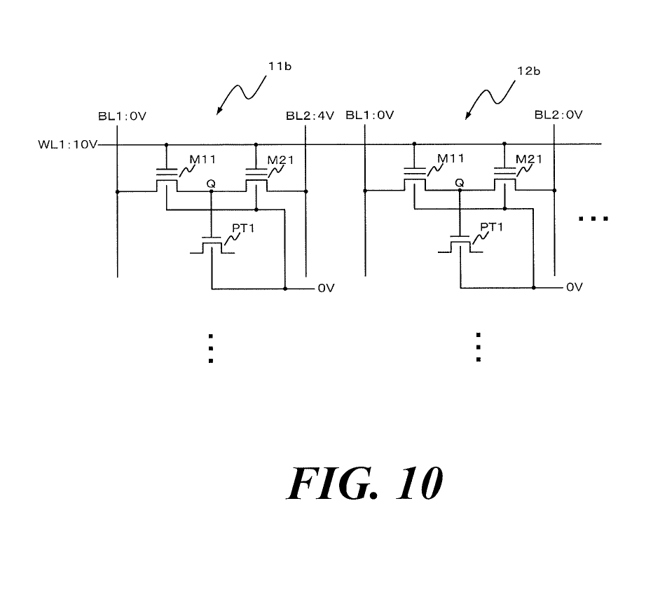

In the case of arranging cells according to the present embodiment like an array, plural cells are connected to the same word line, as illustrated in FIG. 10. In order to prevent, when data is written to one (i.e., a cell 11b) of the cells of a cell array, the data from being written to the other cells (e.g., a cell 12b), it is sufficient to equalize the voltages of the bit lines BL1 and BL2 connected to each of the latter cells (e.g., the cell 12b). Consequently, no CHEs are generated in each of the latter cells (e.g., the cell 12b). Thus, the writing of the data to the latter cells does not occur.

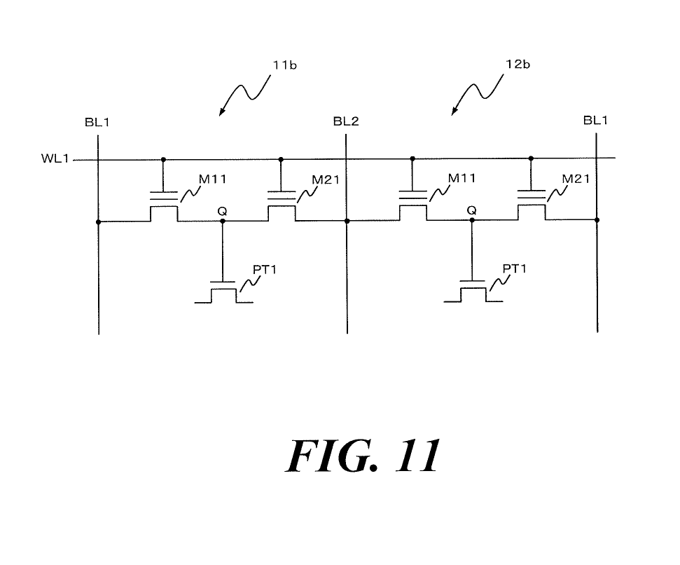

As illustrated in FIG. 11, the bit line can be shared by adjacent cells. Even in this case, writing data only to the cell 11b can be performed, without writing data to the cell 12b, by equalizing, when data is written to the cell 11b, the voltages applied to the bit lines BL1 and BL2 connected to each of the latter cells (e.g., the cell 12b).

According to the present embodiment, there is no need to newly add another element to a cell for the purposes of selectively writing data to the memory transistor and of preventing the breakdown of the gate insulating film of the pass transistor. In addition, the two memory transistors included in each cell are connected to one of the word lines. Thus, according to the present embodiment, a programmable logic switch is implemented, which has a small chip area and which can perform the selective writing of data to the memory transistor so as to prevent a high voltage from being applied to the pass transistor due to the writing of data to the memory transistor.

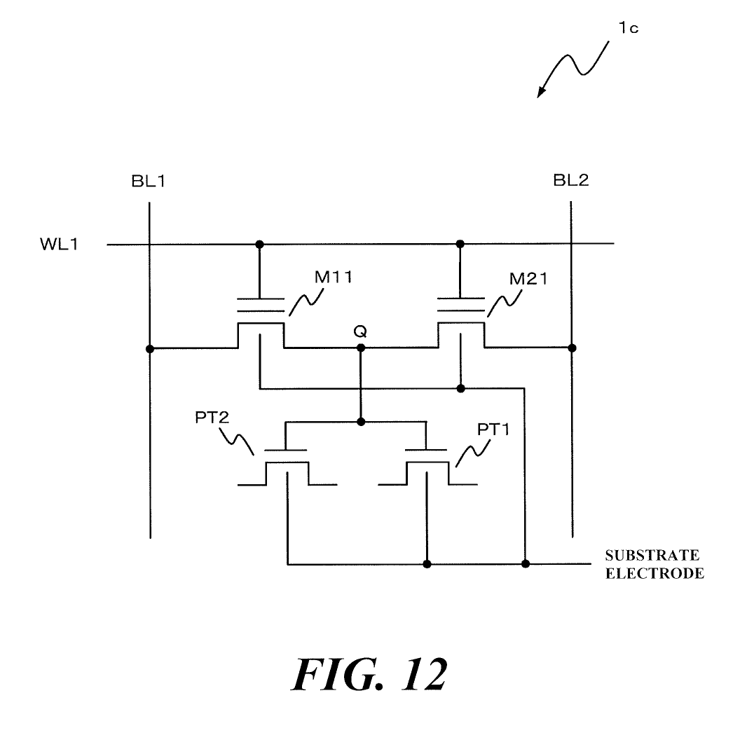

As illustrated in FIG. 12, plural pass transistors may be connected to the node Q in each cell. Alternatively, the node Q may be connected to an input terminal of an inverter. Alternatively, the node Q may be connected to an input terminal of a transfer gate. In any of such cases, a transistor of a pass transistor, an inverter, or a transfer gate is connected to the node Q at the gate electrode thereof.

Incidentally, in the above description, the writing method for writing data to the memory transistor M21 has been described. Writing data to the memory transistor M11 can be accomplished by a similar method. In the case of writing data to the memory transistor M11, the second write voltage is applied to the bit line BL1. In addition, the bit line BL2 is set to the ground voltage.

Although the ground voltage is given to the bit line BL1 and the substrate electrode in the above description, a third write voltage, whose sign is negative, may be given thereto. Increase of electron injection efficiency and reduction of the first write voltage can be expected by setting the voltage of the well of the memory transistor to be negative. However, the third write voltage should be set such that the gate insulating film of the pass transistor is prevented from being broken down by the third write voltage applied to the substrate electrode. The voltage at the node Q, which is obtained when writing data, is substantially equal to the voltage VBL1. Thus, it is necessary that the difference between the voltage given to the bit line BL1 and the third write voltage is equal to or less than the withstanding voltage of the gate insulating film of the pass transistor. For example, if the third write voltage is also given to the bit line BL1, a load given to the gate insulating film of the pass transistor can be minimized. The voltage given to the bit line BL1 and the voltage given to the substrate electrode may be either equal to or different from each other.

### (Erasure Method)

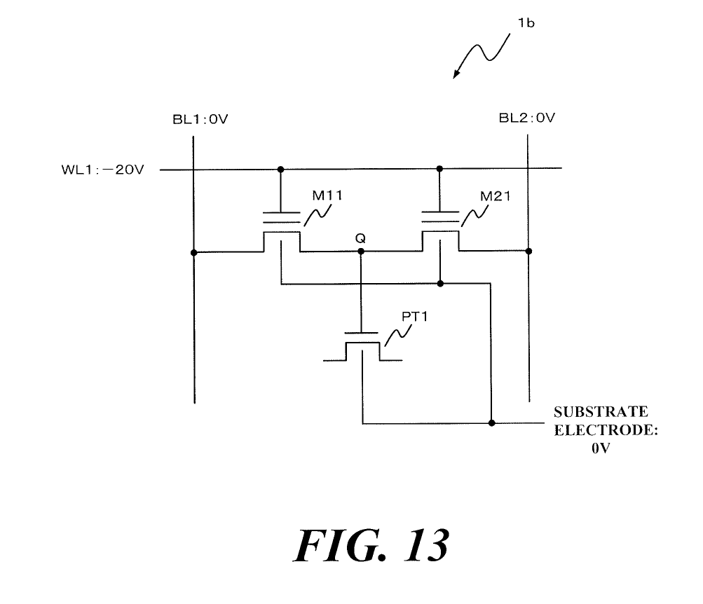

Hereinafter, a method for erasing data from the memory transistor according to the present embodiment is described with reference to FIG. 13. When the memory transistor is put into an erased state, the control circuit applies a negative erasure voltage to the word line WL1. Because the erasure method according to the present embodiment uses FN current, the erasure voltage is set at, e.g., −20 V. According to this erasure method, both of the memory transistors M11 and M21 included in each cell are brought into an erased state. In addition, all of the memory transistors connected to the same word line in the cell array are put into an erased state. The substrate voltage is set at 0 V when data is erased. Thus, no damage is given to the pass transistor PT1.

If the negative erasure voltage is applied to the word line WL1, it is expected that the voltage VQ at the node Q is increased in a negative direction by the capacitive coupling between the gate and the drain of the memory transistor. However, if the voltage VQ is lower than the substrate voltage, current flows through the p-n junction formed between the (P-doped) well of the memory transistor and the (N-doped) source-drain diffusion layer. Thus, the voltage VQ is immediately settled to the same voltage as the substrate voltage. Accordingly, the application of a high voltage to the pass transistor PT1 by the capacitive coupling of the erasure voltage does not occur.

Instead of the above-mentioned erasure method, a positive erasure voltage (e.g., about 20 V) may be applied to the substrate electrode, and a voltage of 0 V may be given to the word line WL1. However, according to the present embodiment, the well is common to the memory transistors M11 and M21 and the pass transistor PT1. Thus, when the erasure voltage is given to the memory transistors M11 and M21, the erasure voltage is also applied to the pass transistor PT1, and, the erasure voltage is output from the pass transistor PT1 through the p-n junction formed between the source/drain and the well thereof. The source/drain of the pass transistor PT1 may be connected to another logic circuit (e.g., the input and output terminals of an inverter), and a transistor of the another logic circuit may have the thin gate insulating film for realizing high-speed operation. When the erasure voltage serving as a high voltage output from the pass transistor PT1 is applied to the another logic circuit, the breakdown of the gate insulating film may be caused in the transistor of the another logic circuit.

On the other hand, if the erasure method according to the present embodiment is used, the voltages of the source and the drain of the pass transistor are not caused to be high. Thus, the logic circuit connected to the pass transistor is allowed to use a high-speed transistor having a thin gate oxide film.

### (Operation Method)

As an operation method of the logic switch according to the present embodiment, the control circuit applies, to the word line WL1, a voltage intermediate between the threshold voltages respectively corresponding to the erased state and the written state. Also, the control circuit applies a first operating voltage and a second operating voltage which is smaller than the first operating voltage to the bit lines BL1 and BL2, respectively. Consequently, the memory transistor in the erased state is put into an on-state, while the memory transistor in the written state is put into an off-state. If the pass transistor is an N-type transistor, the pass transistor becomes an on-state by receiving the first operating voltage applied through the memory transistor in the erased state at its gate, and becomes an off-state by receiving the second operating voltage at its gate. In the operation method, when the voltage applied to the gate of the pass transistor is set to be higher than the voltage of a signal input to the source/drain of the pass transistor, a signal passing through the pass transistor fully swings. Thus, power consumption is reduced, and a delay is decreased. More specifically, the value of the voltage applied to the gate of the pass transistor in an on-state is set to be larger than a value obtained by adding the value of the voltage of the signal to the value of the threshold voltage of the pass transistor.

The value of the voltage applied to the gate of the pass transistor in an on-state is set in the following manner. That is, first, the first operating voltage is given thereto via the memory transistor which is in an erased state. In order to give the first operating voltage to the gate of the pass transistor in a case where the memory transistor is an N-type transistor, it is necessary to set the value of the voltage given to the gate of the memory transistor as being larger than a value obtained by adding the first operating voltage and the threshold value for the pass transistor.

Here, the higher-side voltage of a signal passing through the pass transistor is designated with Vdh, the lower-side voltage thereof is designated with Vdl. The threshold voltage of the pass transistor is designated with Vthpt, and the threshold voltage of the N-type memory transistor in an erased state is designated with Vthm. A voltage which is applied to the word line WL1 and which is a voltage intermediate between the threshold voltages respectively corresponding to the erased state and the written state is designated with Vw1. And, the first operating voltage is designated with V1, and the second operating voltage is designated with V2. In order to give the first operating voltage and the second operating voltage via the memory transistors, it is necessary to satisfy the following relations:

Vw1>Vthm+V1; and

Vw1>Vthm+V2.

Assuming that the first operating voltage is larger than the second operating voltage, it is sufficient to satisfy only the above relation:

Vw1>Vthm+V1.

In addition, considering conditions for allowing, when the pass transistor is an on-state, the signal passing the pass transistor to fully swing, and for inhibiting, when the pass transistor is an off-state, a signal from passing through the pass transistor, it is necessary to satisfy the following conditions:

V1>Vdh+Vthpt; and

V2<Vdl+Vthpt.

In addition, the following relation is derived from the above expressions:

Vw1>Vthm+Vdh+Vthpt.

If the voltages satisfy the above relations, the power consumption is not reduced, and the reduction of the delay is suppressed. In a case where the pass transistor is a P-type transistor, the above expressions can also be represented by similar expressions by setting the threshold voltage Vthpt at a negative value.

### (Layout)

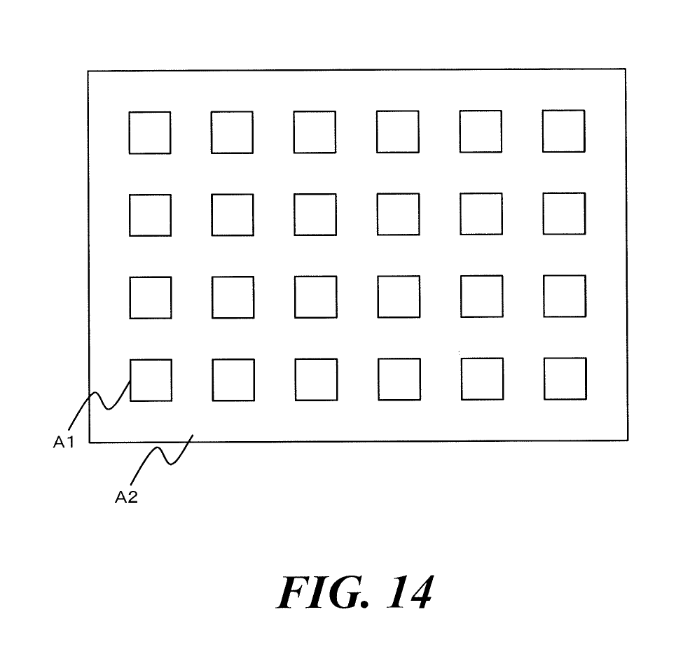

FIG. 14 illustrates an example of the layout of a semiconductor integrated circuit having the logic switch according to the present embodiment. According to the layout of the semiconductor integrated circuit, within a chip, there is at least one region (i.e., a memory transistor area) A1 between regions (i.e., logic transistor areas) A2 in which logic transistor such as the pass transistor PT1 is provided. The bottom surface of the gate electrode of the logic transistor is lower than the bottom surface of the gate electrode of the memory transistor in height from the substrate.

If the above-mentioned layout, the number of wires provided on the chip or a total wiring length can be reduced, so that the chip area can be decreased, because the distance between each memory transistor and the logic transistor can be short, as compared with the layout in which the memory transistors are gathered at one place. Consequently, the chip area can be reduced. If the power supply to the logic switch is resumed after it is once interrupted, the on/off of the pass transistor PT1 can quickly be controlled according to data stored in the memory transistors M11 and M12. Thus, power-shutdown and power-recovery can immediately be achieved. In the conventional technique, since electric-power is supplied through a long wire, power-recovery takes much time, as compared with the present embodiment.

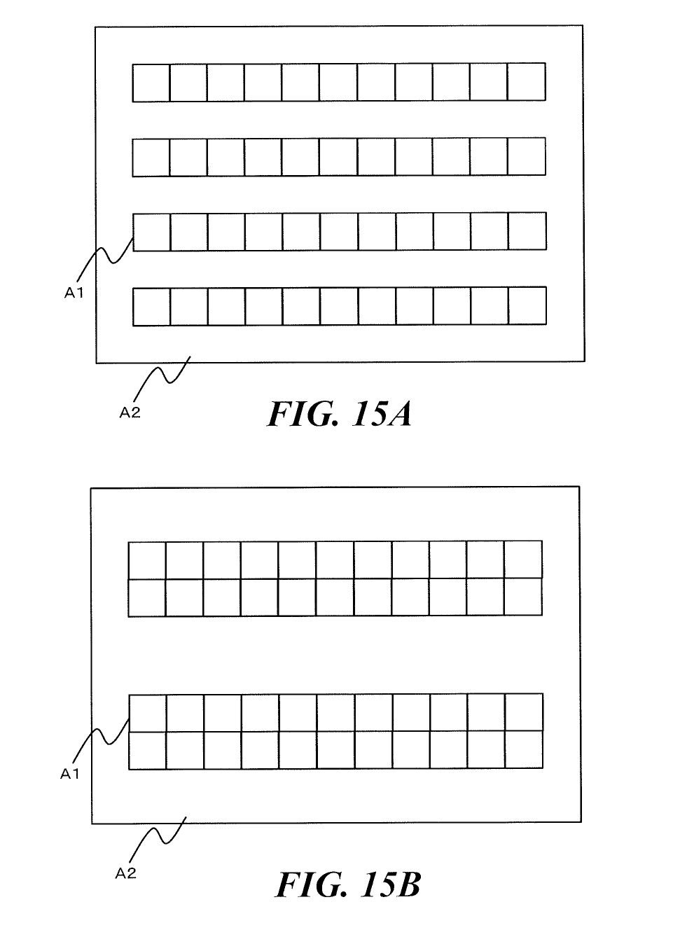

The semiconductor integrated circuit having the logic switch according to the present embodiment may employ layouts respectively illustrated in FIGS. 15A and 15B. A total wiring length can be reduced by sandwiching each memory transistor area A1 between logic transistor areas A2, as illustrated in FIGS. 15A and 15B. In addition, the transistors can be arranged in high density by gathering the memory transistor areas A1. Consequently, the chip area can be reduced.

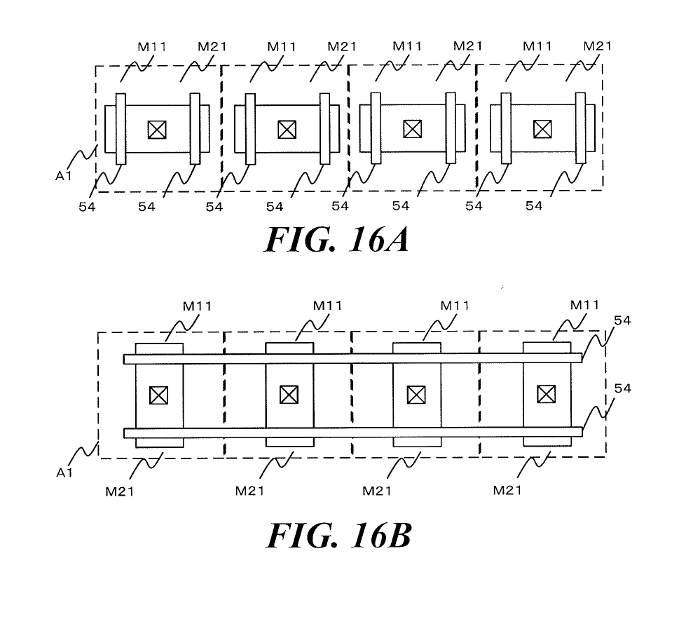

In the layouts illustrated in FIGS. 15A and 15B, plural memory transistors may be arranged in the channel length direction of each memory transistor, which is perpendicular to the direction of the gate electrode, as illustrated in FIG. 16A. Alternatively, as illustrated in FIG. 16B, plural memory transistors may be arranged in the channel width direction of each memory transistor, which is parallel to the direction of the gate electrode. In the case of arranging the transistors, as illustrated in FIG. 16A, a wire for connecting each memory transistor to the logic transistor is short, as compared with the case of arranging the transistors, as illustrated in FIG. 16B. Thus, a recovery time taken to resume the power supply to the logic switch after it is once shut down is short. However, the distance between each memory transistor and the logic transistor does not depend upon the width of STI but depends upon the distance from the gate electrode of each memory transistor to the gate electrode of the logic transistor. Therefore, the chip area is smaller than the value (=120F²) in the case of using SRAM, and larger than the value in the case illustrated in FIG. 16B.

In the case of arranging the transistors, as illustrated in FIG. 16B, the gate electrodes can be shared by plural cells. Thus, it is unnecessary to arrange metal wires as word lines. As compared with the case illustrated in FIG. 16A, the total wiring length can further be reduced. Since the distance between the logic transistors depends upon the width of each STI provided between the logic transistor and the memory transistor, the chip area can be reduced, as compared with the case illustrated in FIG. 16A. However, in the case of the arrangement illustrated in FIG. 16B, each wire which connects the memory transistor to the logic transistor should stride over the gate electrode. Therefore, it is necessary to connect the memory transistor to the logic transistor by raising each connecting wire to a high wiring level in a direction perpendicular to the substrate surface. Because bit lines BL1 and BL2 (not shown in FIGS. 16A and 16B) are arranged in a direction perpendicular to a direction in which each gate electrode extends, the direction in which each bit line extends is the same as the direction of connecting each memory transistor to the logic transistor. Consequently, it is necessary to bypass one of the bit line and the connecting wire. Thus, the layout illustrated in FIG. 16B becomes complex. In addition, the recovery time is relatively long due to the influence of the capacity between the wires, as compared with the case illustrated in FIG. 16A.

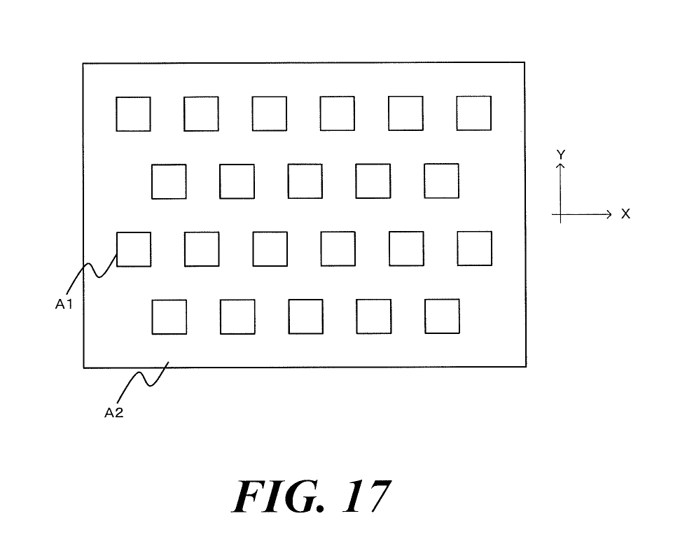

The semiconductor integrated circuit having the logic switch according to the present embodiment may employ a layout as illustrated in FIG. 17. In the layout illustrated in FIG. 17, assuming that a group of the memory transistor areas A1 aligned in a predetermined direction (X-axis direction) is referred to as a “row”, rows are arranged in a direction (Y-axis direction) perpendicular to the X-axis direction by being staggered in the X-axis direction. Although FIG. 17 illustrates a case where each the rows are staggered one by one, for example, the rows may be staggered two by two.

In each of the layouts illustrated in FIGS. 14, 15A, 15B and 17, the memory transistor areas A1 are periodically arranged. In order to minimize “minimum dimensions” allowed in manufacturing process, it is necessary that the memory transistor areas A1 have a periodical structure. In the other words, by adapting a periodical structure, miniaturization can be further promoted. Consequently, the enhancement of an operation speed of the logic switch and the reduction of the chip area can be achieved.

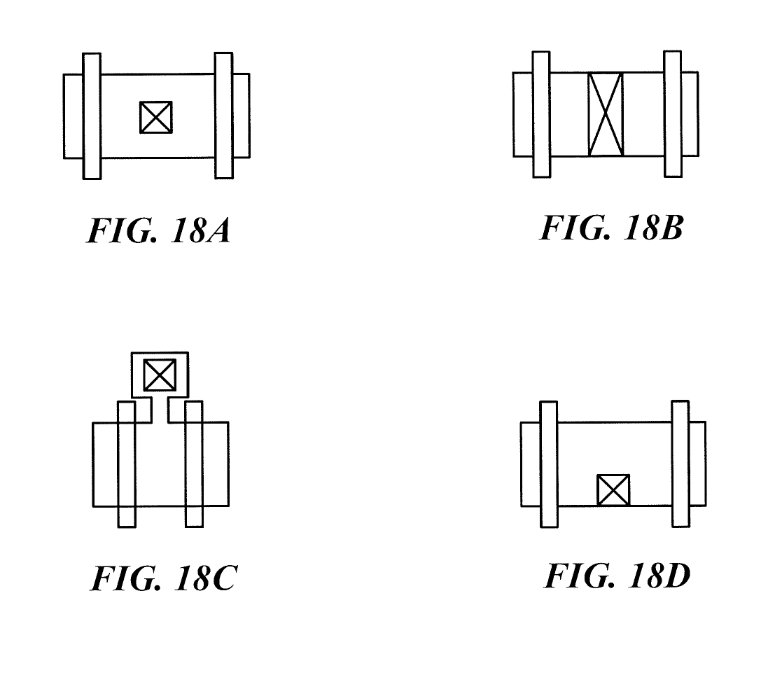

Each of FIGS. 18A to 18D illustrates an example of the layout of memory transistors. The layouts of the plural memory transistors employing the layout of memory transistor illustrated in FIG. 18A as an example of the layout of the memory transistors in each memory transistor area have been described with reference to FIGS. 16A and 16B. However, the layout of the memory transistors in each memory transistor area is not limited to the layout illustrated in FIG. 18A. The layouts respectively illustrated in FIGS. 18B to 18D may be employed as the layout of the memory transistors in each memory transistor area. In the case of providing a contact plug between the memory transistors, as illustrated in FIG. 18A, the metal material of the contact plug serves as a shield, so that the influence of adjacent memory transistors can be eliminated. In addition, occurrence of a malfunction due to the interaction between the memory transistors can be avoided. The influence of the adjacent memory transistors depends upon the distance between the channels of the adjacent memory transistors, the technology node corresponding thereto, the materials of the charge storage layers thereof, the sizes thereof and the like. If the adjacent memory transistors have a profound effect, the contact plug is provided between the adjacent memory transistors such that the memory transistors can be arranged closely to each other. Consequently, shielding effects can be further enhanced by providing the contact plug having a width equal to or wider than the channel width of each memory transistor, as illustrated in FIG. 18B.

If an affection from the adjacent memory transistors is small, the memory transistors can be arranged in a high density by reducing the distance between the memory transistors provided in each cell, as illustrated in FIG. 18C. FIG. 18C illustrates an example of an arrangement in which the distance between the channels of the memory transistors is reduced to a value smaller than the size of the contact plug and in which the contact plug is disposed in a region outside a region provided between the channels of the memory transistors.

In the case of the layout of the memory transistors illustrated in FIG. 18D, the connecting wires each of which connects the logic transistor to an associated memory transistor can be arranged closely to each other, as compared with the case illustrated in FIG. 18A. In addition, a recovery time taken to resume the power supply to the logic switch after it is interrupted can be shorten. Because the contact plug is provided between the memory transistors in the case illustrated in FIG. 18D, the influence of the adjacent memory transistors can be eliminated.

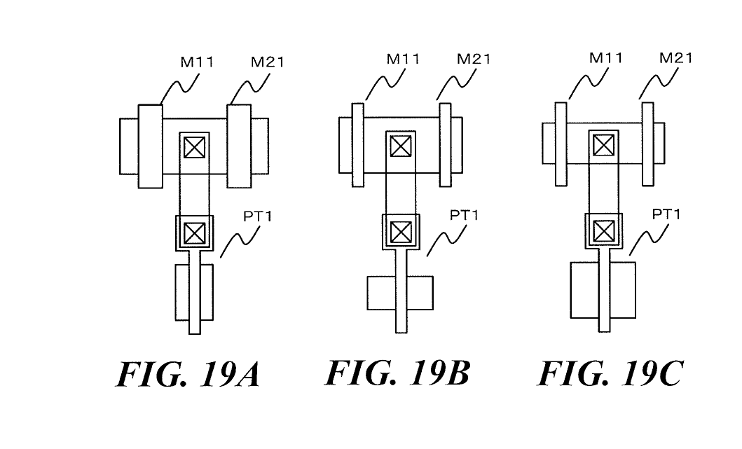

Hereinafter, the channel lengths and the channel widths of the memory transistors and the logic transistor are described with reference to FIGS. 19A to 19C. The channel length of each memory transistor is longer than the channel length of the logic transistor, as illustrated in FIG. 19A. Usually, the SiO₂ equivalent thickness (i.e., the equivalent oxide thickness (EOT)) of the gate insulating film (i.e., the tunnel film, the charge storage film and the block film of the memory transistor) is thicker than the EOT of the logic transistor. Thus, leakage current tends to increase. Accordingly, an off-state current of the memory transistor can be reduced by setting the channel length of the memory transistor to be longer than the channel length of the logic transistor. Consequently, low power consumption can be achieved. FIGS. 19A to 19C illustrate only the logic transistor electrically connected to each memory transistor. However, if the polysilicon width of the adjacent transistor is largely changed, it may be difficult to implement the manufacturing process. In such a case, the channel length of the logic transistor directly connected to the memory transistors may be suppressed to a value nearly equal to the value of the channel length of each memory transistor. In addition, the channel length of the logic transistor that is not connected directly to a memory transistor (not shown) may be gradually reduced to a short value in comparison with the value of the channel length of the memory transistor.

Such different channel lengths have lengths that differ from each other by amounts larger than a manufacturing variation. According to, e.g., International Technology Roadmap for Semiconductors (ITRS), channel lengths one of which differs from the other in length by 10% or more are referred to as “different channel lengths”.

Concerning the channel widths of the memory transistors and the logic transistor, each memory transistor may be larger than the logic transistor in channel width, as illustrated in FIG. 19B. Alternately, each memory transistor may be smaller than the logic transistor in channel width, as illustrated in FIG. 19C. If a signal change occurs at the source and the drain of the logic transistor, noise is generated at the gate electrode thereof due to the capacitive coupling between the gate and the source/drain thereof. At that time, if the channel width of the memory transistor is large, as illustrated in FIG. 19B, an amount of current allowed to flow through the memory transistor is large. Thus, noise generated at the gate of the logic transistor can be reduced. In addition, the logic switch can stably be operated. On the other hand, noise generated at the gate of the logic transistor depends upon the capacity provided between the gate and the source/drain thereof. If the capacity provided therebetween is sufficiently small, an amount of noise generated thereat is reduced. In such a case, there is no need to set an amount of current flowing through the memory transistor to be large. Accordingly, the area of each memory transistor can be reduced by decreasing the channel width thereof.

Thus, according to the present embodiment, a cell of the logic switch includes two nonvolatile memory transistors that the gate is connected to a single word line, and a logic transistor the gate of which is connected to a node at which the source end or the drain end of one of the two memory transistors is connected to the drain end or the source end of the other memory transistor. In addition, regions at each of which an associated one of the memory transistors is provided are separately arranged in a chip. The employment of nonvolatile memory transistors enables the shutdown of electric-power. Thus, power consumption can be reduced. In addition, there is no need to provide two memory transistors such that the source end or the drain end of one of the two memory transistors is connected to a node to which the drain end or the source end of the other memory transistor is connected, in order to perform the selective writing of data to the memory transistors. In addition, in order to arrange each memory transistor and the logic transistor closely to each other, a total wiring length can be reduced. Consequently, the chip area can be decreased.

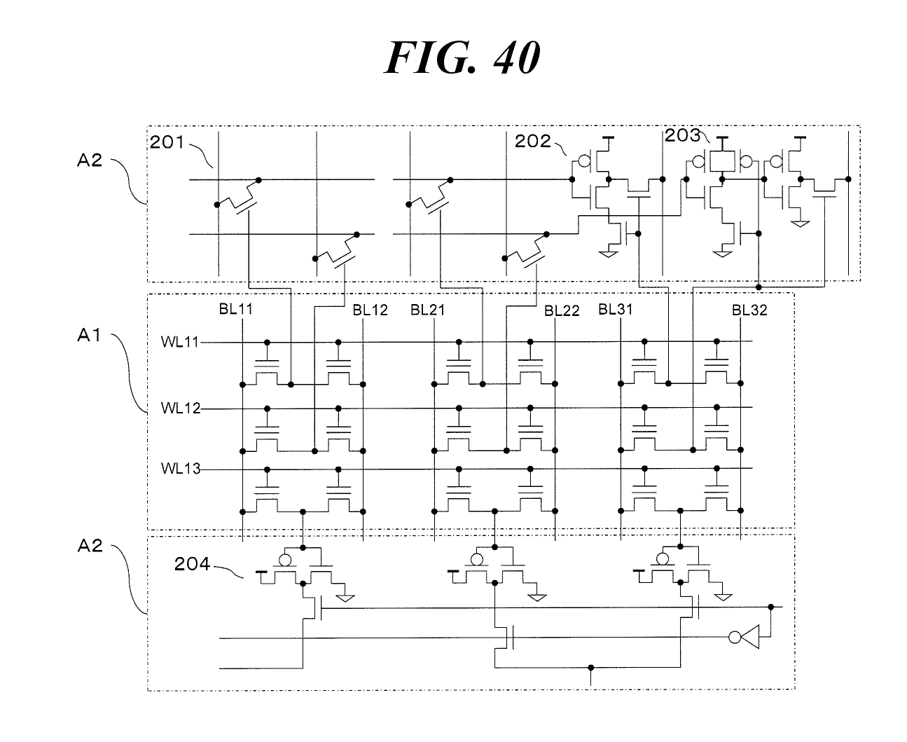

FIG. 40 illustrates a more detailed layout based on the layouts illustrated in FIGS. 14, 15A and 15B. In the layout illustrated in FIG. 40, a memory transistor area A1 is interposed between two logic transistor areas A2. Each memory group is consisting of a pair of memory transistors. Three memory groups are arranged in a predetermined direction, and sets of these memory groups are arranged in a direction perpendicular to the predetermined direction.

In FIG. 40, plural types of switches, each of which is usable in the programmable logic switch, are exemplified. Each switch 201 is the pass transistor which can switch, according to a value stored in the nonvolatile memory, the connection/non-connection of wires respectively connected to both the source and the drain of the transistor.

A switch 202 includes a complementary metal-oxide semiconductor (CMOS) inverter, an N-type pass transistor switch connected to a ground-side terminal of the CMOS inverter, and an N-type pass transistor switch connected an output terminal of the CMOS inverter. When the CMOS inverter is used, although an output direction is limited to one direction, the drivability of the wires is enhanced. Thus a wiring delay is reduced. The on/off of each of the switches respectively connected to the ground-side terminal and the output terminal of the CMOS inverter is controlled according to the value stored in the memory transistor. If the pass transistor switch connected to the output terminal of the CMOS inverter is turned off, the power supply to the CMOS inverter is shut down. Thus, the power consumption of the CMOS inverter can be reduced.

A switch 203 includes, in addition to components (a CMOS inverter and an N-type pass transistor) almost similar to that of the switch 202, a NAND gate connected to an input-side terminal of the CMOS inverter. An output of the corresponding memory transistor is connected to one of the input terminals of the NAND gate. Although a transistor (N-type pass transistor) is not connected to the ground-side terminal of the CMOS inverter in the switch 203 unlike the switch 202, a power-off transistor may be provided similarly to the switch 202. While a logical value of a signal is inverted in the switch 202 because it has only one inverter, in the switch 203, the inversion of the logical value of the signal is not caused. Accordingly, the design of the device is facilitated. If the pass transistor switch is turned off, the power supply to the ground-side terminal of the NAND gate is interrupted. In addition, a P-type transistor at the power-supply voltage side of the NAND gate is turned on. Thus, a signal of a High level is input to the input terminal of the CMOS inverter. Generally, when the voltage at an input terminal of a CMOS inverter is an intermediate value that is neither High level nor Low level, a leakage current of the CMOS inverter will increase. However, according to the switch 203, the increase of the leakage current can be suppressed by shutting down the power supply. At switching in an FPGA operation, no current flows in the P-type transistor of the NAND gate, which is connected to the memory transistor. Thus, the channel length of the P-type transistor may be increased. The channel width thereof may be reduced. Alternatively, plural P-type transistors may be series-connected to the memory transistor. Consequently, when the pass transistor is turned off, the leakage current of the NAND gate itself can be reduced when the pass transistor is turned off.

A switch 204 has a structure almost similar to that of the switch 202. The pass transistor thereof is connected to an output terminal of the CMOS inverter. However, an output terminal of the memory transistor is directly connected to an input terminal of the CMOS inverter. Another signal other than the output signal from the memory transistor is connected to the gate of the pass transistor. Consequently, a logical operation can be performed using a signal other than the output signal from the memory transistor, thereby forming, e.g., a look-up table (LUT).

In the case of any of the above switches, an output of the memory transistor is connected only to the gate electrode of the logic transistor. In the foregoing description, the case of using the N-type transistor as the pass transistor is exemplified. In the case of using a P-type transistor as the pass transistor, the switch will be connected to the memory transistor by, e.g., appropriately performing a logical inversion, especially, in the switches 202 and 203, so that the power supply to the CMOS inverter and the NAND gate is interrupted when the pass transistor is turned off.

### (Requirements of Charge Storage Film)

In the case of using a MONOS type transistor as the memory transistor according to the present embodiment, preferably, in the charge storage film, a deviation of electric-charge injected thereinto is small, as will be described below.

The electric charge trap level of silicon nitride (SiN) used in the charge storage film 52 of the present embodiment differs according to the content rates of Si and N. Assuming that the proportion of a molar ratio of Si in SiN to a molar ratio of N is referred to as N/Si ratio, a Si atom has four unpaired electrons, and an N atom has three unpaired electrons. Therefore, a stoichiometric composition ratio N/Si of N and Si is 1.33 (N/Si=1.33). A SiN film whose N/Si ratio is 1.33 is referred to as a stoichiometric SiN film, and a SiN film whose N/Si ratio is smaller than that of the stoichiometric SiN film is referred to as a Si-rich SiN film. Here, the Si-rich SiN film is shallower in electron trap level than the stoichiometric SiN film. Thus, electrons in the film are relatively easy to move.

If a stoichiometric SiN film is used as the charge storage film 52, electrons injected into the charge storage film locally exist and are trapped by writing data. When writing data, CHEs are generated at the drain end of the memory transistor. Thus, electrons trapped in the charge storage film by writing data using CHEs are concentrated at the drain side. Accordingly, asymmetry may occur in the voltage distribution in the channel of the memory transistor.

In an n-channel transistor, one of source-drain diffusion regions, which is higher in voltage than the other source-drain diffusion region, is defined as a “drain”. The other source-drain diffusion region which is lower in voltage than the “drain” is defined as a “source”. Thus, the channel resistance of the transistor is largely dominated by a source-side voltage barrier. For example, it is assumed that electrons of the same amount are injected into each of the charge storage films of the two memory transistors, that a larger amount of electrons are stored in a drain-side part of the charge storage film of one of the memory transistors, and that a larger amount of electrons are stored in a source-side part of the charge storage film of the other memory transistor. The memory transistor adapted to store a larger amount of electrons in the source-side part of the charge storage film can strongly modulate the voltage of the source, so that change of the threshold voltage Vth is increased (see, e.g., IEEE ELECTRON DEVICE LETTERS, Vol. 21, pp. 543 to 545, 2000).

Thus, it is considered that when electrons locally exist in the charge storage film in the vicinity of the drain due to the writing using CHEs and are trapped, the threshold voltage Vth is not sufficiently changed in some source-drain voltage application direction.

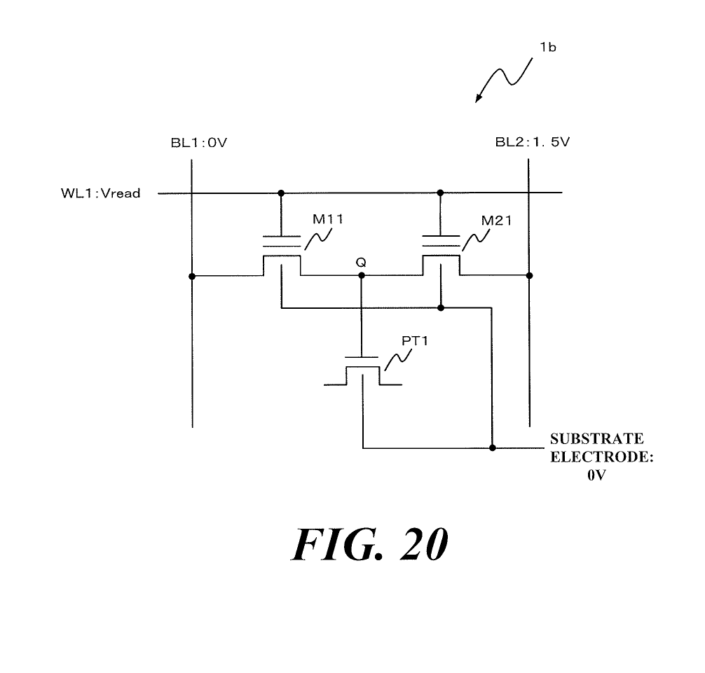

If the threshold voltage Vth is not sufficiently changed, the logic switch may not be appropriately operated. The case of applying a voltage to each wire of the cell 1b to operate the logic switch, as illustrated in FIG. 20, is described hereinafter by way of example. It is assumed that the memory transistor M11 is in an erased state, while the memory transistor M21 is in a written state. At that time, a voltage of 0 V is applied to the gate of the pass transistor via the memory transistor M11. Under this operating condition, one of the source-drain diffusion regions of the memory transistor M21, which is connected to the node Q, corresponds to the “source”, while the source-drain diffusion region thereof connected to the bit line BL2 corresponds to the “drain”. If the electrons injected into the charge storage film by means of CHEs locally exist at the “drain” side in the charge storage film, the threshold voltage Vth for the memory transistor M21 is not sufficiently high. Consequently, a large channel leakage current may be generated in the memory transistor M21. In addition, power consumption may increase. Alternatively, the memory transistor M21 may fail to block the voltage applied to the bit line BL2, so that a malfunction of the logic switch may occur.

Thus, it is preferable that when data is written to the memory transistor, electrons are caused to distribute in the source-side part of the charge storage film. However, in the case of using a stoichiometric SiN film as the charge storage film, it is necessary to increase a write time in order to implement, on the source-side part of the charge storage film, the distribution of the electrons injected when the memory transistor is put into a written state.

On the other hand, in the case of using a Si-rich SiN film as the charge storage film 52, the trap level of the Si-rich SiN film is shallow, as compared with the trap level of the stoichiometric SiN film. Thus, electrons are easy to move in the Si-rich SiN film. Accordingly, electrons injected into the drain end by writing data move in the charge storage film 52 and are diffused to the source end. Thus, if the logic switch is operated by applying a voltage to each wire of the cell 1b, as illustrated in FIG. 20, the threshold voltage of the memory transistor M21 which is in a written state can be maintained at a high-level. Consequently, the reduction of the leakage current and the prevention of a malfunction of the logic switch can be accomplished. At that time, it is unnecessary to increase a write time, the increase of which is needed in the case of using the stoichiometric SiN film as the charge storage film.

As the N/Si ratio decreases, the electrons injected into the charge storage film become more easily to move. However, when the N/Si ratio reaches 0.67, since this ratio corresponds to a composition in which averagely, two of four bonds of Si are converted into dangling bonds, or in which adjacent Si atoms form a covalent bond, there will be a large number of covalent bonds. Thus, the insulation property of the SiN film is deteriorated, so that gate leakage current extremely increases. Accordingly, it is desirable that the N/Si ratio is larger than 0.67 and smaller than 1.33. The composition of the charge storage film can be known by being analyzed according to an electron energy-loss spectroscopy (EELS).

In the case of using a Si-rich SiN film as the charge storage film, because the trap level is shallow, it is frequent that the trapped electrons go out of the charge storage film to the substrate via the tunnel film 51 or to the gate electrode 54 via the block film 53 due to energy obtained from heat. This means that a data retention time of the memory transistor is shorten. A proportion of the electrons caused to go out to the substrate is larger than that of the electrons caused to go out to the gate electrode 54. Therefore, in order to improve the data retention time of the memory transistor, it is necessary to prevent electrons trapped in the charge storage film 52 from going out to the substrate side.

Thus, the N/Si ratio of the charge storage film 52 is changed in this film in a stacking direction. More specifically, a portion of the charge storage film 52, which portion is located in the vicinity of the tunnel film 51, is increased in the N/Si ratio in order not to degrade the retention characteristic thereof. On the other hand, another portion of the charge storage film 52, which portion is located in the vicinity of the block film 53, is decreased in the N/Si ratio in order to facilitate the movement of electric-charge in this film. Consequently, an amount of change of the threshold voltage Vth due to the writing of data can be increased. In addition, the data retention time of the memory transistor can be increased. In the case of the memory transistor used as a file memory, the increasing of the N/Si ratio of a portion of the charge storage film, which portion is in the vicinity of the tunnel film 51, is not permitted, because an erasure time is long. However, the memory transistors used in the programmable switch according to the present embodiment is predominantly low in rewriting-frequency, as compared with the memory transistor used as a file memory. Therefore, the increase of the erasure time is not problematic. The increasing of the N/Si ratio of a portion of the charge storage film 52, which portion is in the vicinity of the tunnel film 51, has a great advantage.

Although the case of using a silicon nitride film as the charge storage film 52 has been described, even in the case of using a silicon oxynitride film as the charge storage film 52, electrons can be prevented using a Si-rich silicon oxynitride film from locally existing.

### (Requirements of Block Film)

In the case of using MONOS type transistors as the memory transistors according to the present embodiment, it is preferable that the block film 53 of each memory transistor is made of a material or film with low charge permeability. The charge storage film 52 in a typical flash memory exchanges charges to and from the substrate. Therefore, it is not preferable that the charge storage film 52 exchanges electric-charges to and from other portions (such as the gate electrode 54). In the case of applying the memory transistor to the logic switch like the present embodiment, a problem may be caused by injecting electric-charges from the gate electrode 54 to the charge storage film 52 or by discharging electric-charges (back-tunneling) from the charge storage film 52.

For example, in the case of using a SiN film as the charge storage film 52 and employing silicon oxide (e.g., SiO₂) or a Si-based material such as SiN and the like as the material of the block film 53, when an erasure operation is performed, a small number of electrons moved from the gate electrode 54 to the charge storage film 52 due to back-tunneling. Thus, reduction of the threshold voltage Vth is inhibited. Accordingly, the threshold voltage Vth for the memory transistor in an erased state becomes equal to or higher than 0 V. When the logic transistor is operated, a voltage (i.e., a read voltage) applied to the gate electrode of the memory transistor should be set to be larger than the threshold voltage Vth corresponding to an erased state. That is, in this case, it is necessary to apply a positive read voltage to the gate electrode. Typically, the read voltage is about 4 V.

When the logic switch operates, it is necessary to always apply the read voltage to the memory transistor. Error writing of data to the memory transistor being in an erased state may be caused by thus always applying a positive read voltage to the memory transistor. Accordingly, a malfunction of the logic switch may occur. Generally, if a voluntary memory is used as a file memory, a read voltage is not applied to the nonvolatile memory in a retention state. However, if the nonvolatile memory is applied to the logic switch, similarly to the present embodiment, long-term reliability in a state of always applying a read voltage to the nonvolatile memory should be ensured.

Thus, back-tunneling is suppressed using the block film 53 with low charge permeability in the memory transistor. Consequently, the long-term reliability of the logic switch is ensured.

A first example of the block film 53 with low charge permeability is a block film made of a highly insulating substance whose relative permittivity with respect to the permittivity of vacuum is higher than the relative permittivity of SiN (i.e., 7.0). The insulating substance is, e.g., aluminum oxide or hafnium oxide. As the permittivity of the block film 53 increases, the electrostatic coupling between the gate electrode and the substrate becomes stronger. Accordingly, even if the physical thickness of the block film 53 is increased, an electric field applied between the gate electrode and the substrate can be maintained at a high level. If the physical thickness of the block film 53 is increased, the efficiency in exchanging electric-charges between the gate electrode 54 and the charge storage film 52 is reduced. Consequently, back-tunneling can be prevented from occurring at the writing of data to and at the erasing of data from the memory transistor.

Thus, the threshold voltage Vth corresponding to the erased state of the memory transistor can be reduced to a negative value by preventing back-tunneling. Consequently, when the logic switch operates, a read voltage applied to the gate electrode 54 of the memory transistor can be set at 0 V. That is, the state of the memory transistor can be prevented from being changed due to the fact that a nonzero read voltage is always applied thereto when the logic switch operates. In addition, because the read voltage can be set at 0 V, there is no need to provide a power supply exclusively used to supply a read voltage.

The threshold voltage can be obtained, e.g., in the following way. That is, first, a voltage of 50 milli-volts (mV) is applied to between the source and the drain of the transistor. Then, a source-drain current IDS is measured while the gate voltage is changed. Assuming that the channel width of the transistor is designated with W, and that the channel length of the transistor is designated with L, a gate voltage, according to which the following relation holds: IDS*L/W=10 nano-amperes (nA), is defined as a threshold voltage.

In addition to the use of the above block film 53, a metal material whose work function has a value larger than a value (4.05 electron volts (eV)) of the work function of high-density n-doped polysilicon is used as the material of the gate electrode 54 of the memory transistor. For example, tantalum, tungsten and titanium nitride are used as such a metal material. As the value of the work function of the gate electrode 54 increases, the electron barrier height of the block film 53 becomes higher, which is evaluated with respect to the gate electrode 54. Thus, back-tunneling can be prevented from occurring while an erasure operation of the memory transistor is performed.

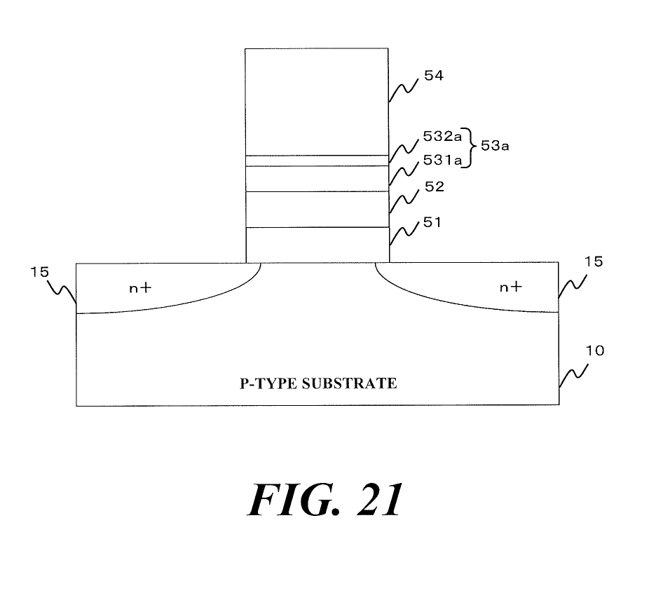

FIG. 21 illustrates a second example of the block film with low charge permeability. A block film 53a of the memory transistor illustrated in FIG. 21 includes an insulating film 531a provided on the charge storage film 52 and another insulating film 532a provided on the insulating film 531a. The gate electrode 54 provided on the insulating film 532a is made of high-density n-doped polysilicon or high-density p-doped polysilicon. The compatibility between a manufacturing process of the transistor according to the present embodiment and a conventional manufacturing process of a transistor can be enhanced using polysilicon as the material of the gate electrode 54. In addition, the manufacturing cost of the transistor can be suppressed.

The material of the insulating film 531a is an insulating material which has a permittivity higher than that of SiN and is, e.g., aluminum oxide or hafnium oxide. The material of the insulating film 532a is SiN. A high-permittivity material is used as the material of the insulating film 531a. Thus, the physical thickness of the insulating film 531a can be increased while the level of the electric field applied between the gate electrode and the substrate is maintained. Consequently, occurrence of back-tunneling is prevented by increasing the thickness of the insulating film 531a. The electric field caused at the gate electrode end during erasure of the memory transistor is reduced in magnitude by providing the insulating film 532a made of SiN on the insulating film 531a. Thus, back-tunneling is more suppressed.

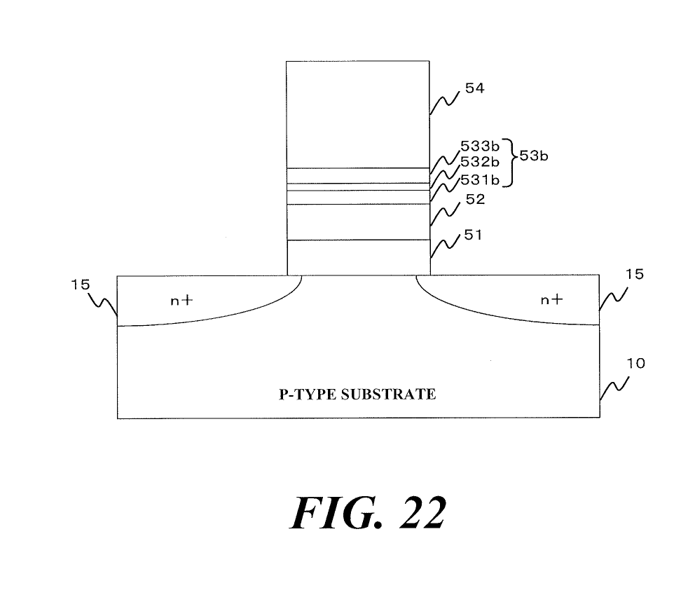

FIG. 22 illustrates a third example of the block film with low charge permeability. A block film 53b of the memory transistor illustrated in FIG. 22 includes an insulating film 531b provided on the charge storage film 52, another insulating film 532b provided on the insulating film 531b and another insulating film 533b provided on the insulating film 532b. The gate electrode 54 provided on the insulating film 533b is made of high-density n-doped polysilicon or high-density p-doped polysilicon. The material of the insulating film 531b is SiO₂. The material of the insulating film 532b is an insulating material which has a permittivity higher than that of SiN and is, e.g., aluminum oxide and hafnium oxide. The material of the insulating film 533b is SiN. In addition, the film-thickens of the insulating film 532b is set to be equal to or less than 1 nm.

Purposes of inserting the insulating film 532b between the insulating films 531b and 533b are to generate an electric dipole due to a high-permittivity material between the insulating films 531b and 533b, and to increase the barrier height of the insulating film 531b on the interface between insulating films 531b and 532b. Consequently, the back-tunneling from the gate electrode 54 to the charge storage film 52 is suppressed from occurring during an erasure operation (see, e.g., K. Kita, “Intrinsic Origin of Electric Dipoles Formed at High-k/SiO₂ Interface”, IEEE International Electron Devices Meeting 2008). In addition, the magnitude of the electric field at the gate electrode end, which is caused during an erasure operation of the memory transistor, is reduced by providing the insulating film 533b on the insulating film 532b. Consequently, the effects of back-tunneling are more suppressed.

In the case of inserting the insulating film 532b between the insulating films 531b and 533b like the present embodiment, the thickness of the insulating film 532b can be reduced. Thus, the thickness of the insulating film 532b is reduced to an extremely small value. Consequently, substantially no change of a conventional processing process for memory transistors that use only Si-based materials is needed. In addition, the deterioration of the memory characteristic due to the diffusion of high-permittivity materials into the charge storage film 52 can be prevented by providing the insulating film 531b made of SiO2 between the charge storage film 52 and the insulating film 532b made of a high-permittivity material.

### (Manufacturing Method)

Hereinafter, a manufacturing method for a programmable logic switch according to the present embodiment is described. The following description is made by assuming that each memory transistor is a MONOS-type transistor using silicon nitride as the material of the charge storage film. Briefly, a programmable logic switch according to the present embodiment is manufactured as follows. That is, first, the formation of STI (shallow trench isolation) and the deposition of the insulating films of the memory transistors are performed. Then, the insulating film of the pass transistor is formed. In addition, the processing of the gate electrodes and gate insulating films of the memory transistors and the pass transistor is performed. Then, wiring is performed.

### (1) Manufacture of STI and Deposition of Insulating Films of Memory Transistors

Either of the manufacture of STI and the deposition of the insulating films of the memory transistors may be performed before the other. That is, STI may be manufacture after the insulating films of the memory transistors are deposited. Alternatively, the insulating films of the memory transistors may be deposited after STI is manufactured.

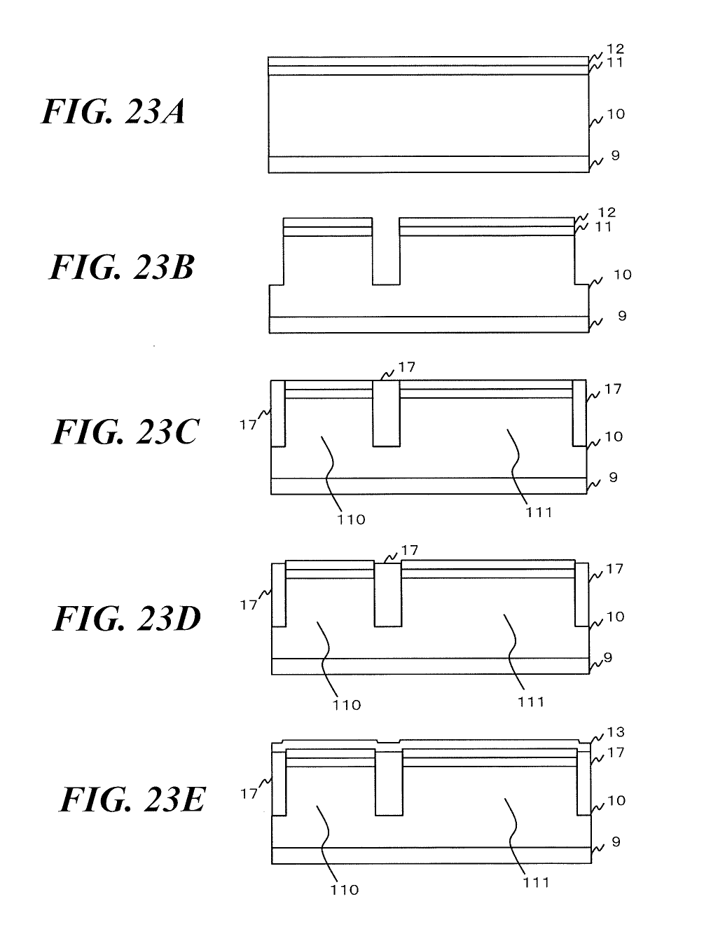

FIGS. 23A to 23E illustrate a process of forming STI after the insulating films of the memory transistors are deposited. First, as illustrated in FIG. 23A, acceptor ions are injected into a substrate 9. Thus, a well 10 is formed. Then, an oxide film 11 serving as a tunnel film of each memory transistor is formed on the entire (top) surface of the substrate 9. A nitride film 12 serving as a charge storage film is formed on the oxide film 11. Then, masking is performed on element regions (i.e., active areas) by lithography or the like. Next, each of the nitride film 12, the oxide film 11 and the substrate 9 is partly etched by dry-etching (see FIG. 23B). Then, SiO₂ film is deposited so as to embed a groove formed on the substrate 9. Thus, STI 17 is formed (see FIG. 23C). Consequently, element regions 110 and 111 are formed.

Preferably, the surface of the STI 17 is located higher than parts of the substrate 9, which respectively correspond to the element regions 110 and 111, and lower than the surface of the nitride film 12. Thus, wet-etching is performed (see FIG. 23D) such that the surface of the STI 17 is located higher than the parts of the substrate 9, which respectively correspond to the element regions 110 and 111, and lower than the surface of the nitride film 12.

Then, an oxide film 13 serving as the block film is formed (see FIG. 23E). Thus, a structure is formed such that the nitride film 12 serving as the charge storage film is covered with the oxide film 13 serving as the block film by forming the oxide film 13 after setting the surface of the STI 17 to be lower than the surface of the nitride film 12. Consequently, a coupling ratio between the charge storage film and the gate electrode is enhanced. Efficiency in writing data to the memory transistor and in erasing data from the memory transistor is improved.

Thus, in the case of depositing the insulating films of the memory transistors before the manufacture of the STI, etching is performed on a region in which the STI 17 is manufactured, in a state in which the oxide film 11 and the nitride film 12 are stacked. Consequently, as viewed in a gate cross-section in a direction perpendicular to the channel of each memory transistor, end portions in a channel width direction (a process end processed by the dry-etching) of the tunnel film and the charge storage film constitute surfaces continuous to the boundaries between the STI 17 and each of the element regions 110 and 111. Accordingly, the electric field generated between the charge storage film and the substrate becomes uniform. When data is written to the memory transistor, electrons can uniformly be injected into the charge storage film from the substrate.

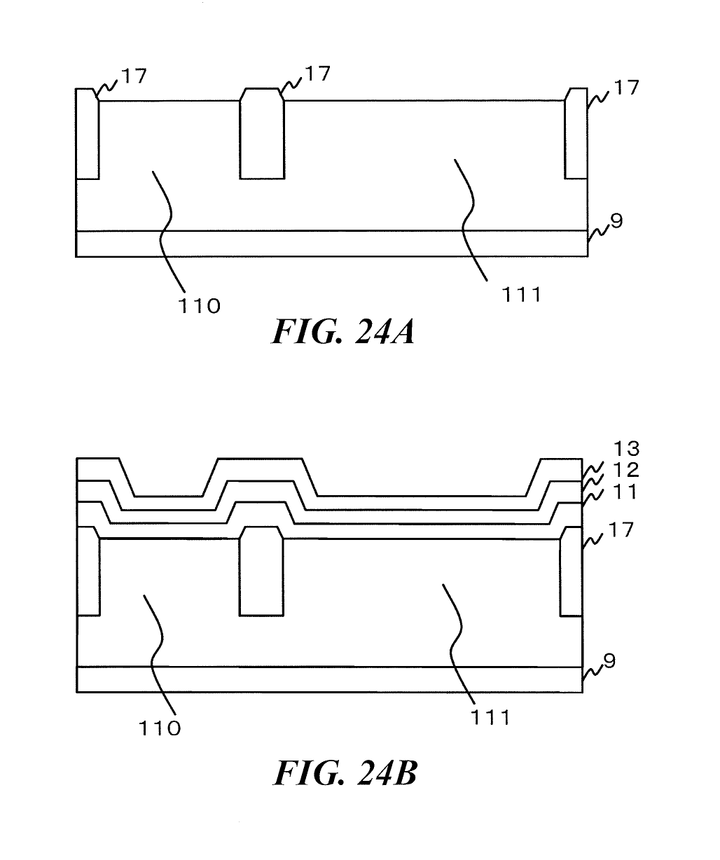

FIGS. 24A and 24B illustrate a process in the case of depositing the insulating films of the memory transistors after the manufacture of STI. First, acceptor ions are injected into a substrate 9. Thus, a well 10 is formed. Then, masking is performed on element regions (active areas) by lithography or the like. Next, the substrate 9 is partly etched by dry-etching. Then, SiO₂ film is deposited so as to embed a groove formed on the substrate 9. Thus, STI 17 is formed. Consequently, element regions 110 and 111 are formed (see FIG. 24A).

Preferably, the surface of STI 17 is located higher than the surface of the substrate 9 at each of the element regions 110 and 111. In addition, preferably, the height of the surface of the STI 17 from the surface of the substrate 9 is set to be equal to or less than a sum of the physical thicknesses of the tunnel film, the charge storage film and the block film.

If the surface of the STI 17 is located lower than the surface the substrate 9 at each of the element regions 110 and 111, a corner of the substrate 9 is exposed. Thus, in a process of forming the gate insulating film of the pass transistor, which will be described below, when the substrate is oxidized, oxidization may become insufficient. This may cause increase of gate leakage current.

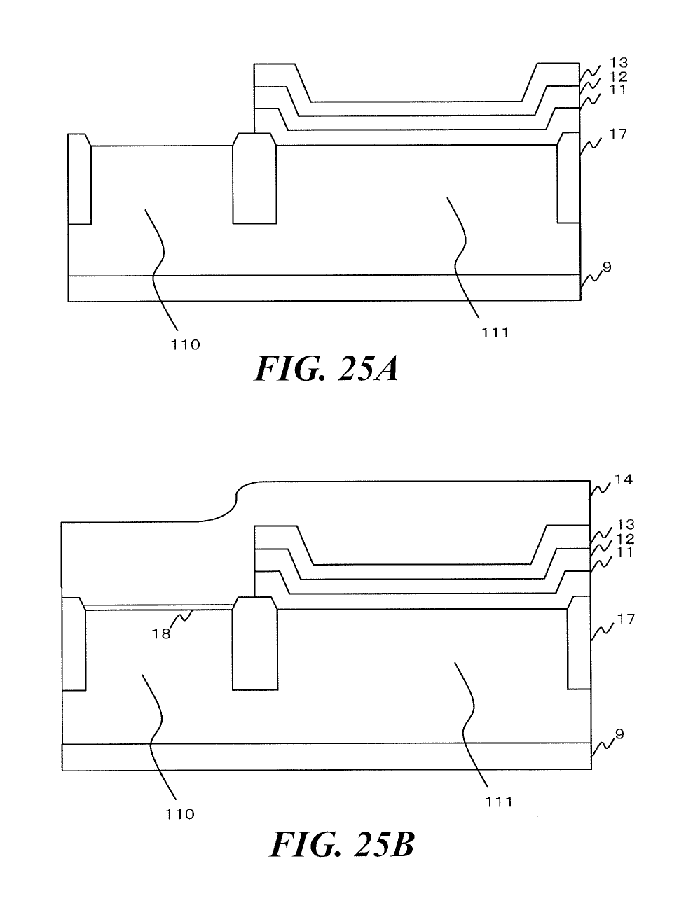

If the height of the surface of the STI 17 is larger than a sum of the physical thicknesses of the tunnel film, the charge storage film and the block film, the dimensions of the gate patterns may differ from intended dimensions when lithography of the gate patterns of the memory transistors and the pass transistor is performed in a process which will be described below. If the lithography of the gate pattern of each memory transistor and the lithography of the gate pattern of the pass transistor are performed collectively, the height from the substrate to the top surface of each of the materials of the gate electrodes respectively corresponding to the memory transistors and the pass transistor may differ from one another when the materials of gate electrodes are deposited on the element region 111 in which each memory transistor is formed, and the element region 110 in which the pass transistor is formed, respectively, as illustrated in FIG. 25B which will be described below. It is necessary to determine a focus height for exposure such that the influence of the difference in height is minimized.

If a focus height for providing optimum exposure of the element region 111, in which each memory transistor is formed, is set as a reference height, a focus height for providing optimum exposure of the element region 110, in which the pass transistor is formed, is lower than the reference height by a sum of the physical thicknesses of the tunnel film, the charge storage film and the block film of each memory transistor. In addition, a focus height for providing optimum exposure of the STI region 17 is higher than the reference height by the height of the STI. If the height of the surface of the STI 17 is higher than a sum of the physical thicknesses of the tunnel film, the charge storage film and the block film, the difference between the focus height for providing optimum exposure of the STI region 17 and the focus height for providing optimum exposure of the element region 110 is large. Thus, no height may be determined as a focus height for providing both of optimum exposure of the STI region 17 and optimum exposure of the element region 110.

Preferably, a side surface of a part of the STI 17 which projects from the surface of the substrate 9 form an angle with the surface of the substrate 9 which is equal to or more than 90 degrees. Consequently, in the cases of writing data to or erasing data from memory transistors manufactured by the process which will be described below, a strong electric field can be prevented from locally being applied to the tunnel film provided along the boundary between the STI 17 and each of the parts of the substrate 9.

As illustrated in FIG. 24B, after the STI 17 is formed, the oxide film 11 serving as the tunnel film of the memory transistor is formed. The nitride film 12 serving as the charge storage film is formed on the oxide film 11. Then, the oxide film 13 serving as the block film is formed on the nitride film 12. Consequently, a sum of the thicknesses in a direction perpendicular to the substrate 7 of the oxide film 11, the nitride film 12 and the oxide film 13 becomes larger than the thicknesses of the central parts of the element regions 110 and 111 in the vicinity of the boundary between the STI 17 and each of the element regions 110 and 111.

### (2) Manufacture of Insulating Film of Pass Transistor

It is necessary to form the tunnel film, the charge storage film, the block film of each memory transistor and the gate insulating film of the pass transistor as different films. Thus, the insulating film of the pass transistor may be manufactured after all of the oxide film 11, the nitride film 12 and the oxide film 13 in the element region 110 are eliminated. Alternatively, while all of the oxide film 13 and the nitride film 12 of the element region 110 in which the pass transistor is formed are removed, a part or all of the oxide film 11 may be left as the insulating film of the pass transistor.

FIGS. 25A and 25B illustrate a process in the case of eliminating all of the oxide film 11, the nitride film 12 and the oxide film 13 in the element region 110 in which the pass transistor is manufactured. First, as illustrated in FIG. 25A, all of the oxide film 11, the nitride film 12 and the oxide film 13 in the element region 110 are removed. Then, thermal oxidation is performed to thereby manufacture an insulating film 18 in the element region 110, as illustrated in FIG. 25B. Then, a gate electrode material 14 is deposited on the films. Thus, if the insulating film 18 of the pass transistor is manufactured after the substrate 9 is exposed by removing all of the oxide film 11, the nitride film 12 and the oxide film 13 provided on the element region 110, a process of manufacturing the insulting film of the pass transistor and a process of depositing the gate electrode material 14 can consecutively be performed. Consequently, the degradation of the performance of the pass transistor due to the formation of the interface state between the gate insulating film (e.g., made of SiO₂) and the gate electrode can be suppressed.

The gate electrode material 14 may be, e.g., polysilicon, a metal material, or metal and polysilicon layer stacks. High-melting-point metal such as tantalum, titanium, tungsten and molybdenum, or carbides and nitrides of such metal, or aluminum compounds, e.g., TaC, TaN, TiN, TiCN, TiAlN, W, WN and Mo, can be used as the metal material. In the case of using polysilicon as the gate electrode material, ion injection is performed, if necessary.

In the element regions 110 and 111, films are simultaneously formed using the gate electrode materials. Although films can be formed using the gate electrode materials in each of the element regions, if the number of processes for manufacturing gate electrodes increase, interface states are formed in the memory transistors and the pass transistor. Thus the performance of the transistors is degraded. Thus, films are simultaneously formed using the gate electrode materials in the element regions 110 and 111 to thereby minimize the number of processes for manufacturing the gate electrodes. Consequently, the degradation of the reliability of the memory transistors and the reduction of the speed of the pass transistor are suppressed.

A method for eliminating the oxide film 11, the nitride film 12 and the oxide film 13 of the element region 110 may be a method using only dry-etching, a method using only wet-etching, or a method of etching part of the oxide film 13, the nitride film 12 and a part of the oxide film 11 by dry-etching and next etching the rest of the oxide film 11 by wet-etching.

Dry-etching excels in anisotropy. Each of the oxide film 11, the nitride film 12 and the oxide film 13 can accurately be processed into resists, using dry-etching. In addition, dry-etching is effective in chip miniaturization. If an appropriate etching gas is selected, plural films can be processed at once using the same etching-gas. Time taken to processing is short.

Wet-etching excels in selectivity among the substrate (Si), the oxide film 11, the nitride film 12 and the oxide film 13. Thus, as compared with the dry-etching, damage given to the substrate 9 is extremely low. Because the wet-etching uses no vacuum process, etching can be performed at low cost.

In the case of etching the oxide film 13, the nitride film 12 and a part of the oxide film 11 by dry-etching, and then etching the rest of the oxide film 11 by wet-etching, both of the advantages of the dry-etching and the wet-etching can be utilized. That is, because the oxide film 13 and the nitride film 12, which have thicknesses that occupy a large part of thicknesses of the insulating films of the memory transistors, are etched by dry-etching, each of the oxide film 13 and the nitride film 12 can accurately be processed into the shape of a resist-pattern. In addition, because the rest of the oxide film 11 is etched using wet-etching, the substrate can be prevented from being damaged.

In the case of using both of the dry-etching and the wet-etching, if the material of the oxide film 11 is SiO₂, it is preferable that a film made of a material, such as SiN or amorphous silicon, differing from SiO₂ is formed on the oxide film 13. The reason is that when the rest of the oxide film 11 is etched by wet-etching after a part of the oxide film 11 is subjected to dry-etching, if the material of the topmost surface of the oxide film 13 is the same as the material of the oxide film 11, i.e., SiO₂, the thickness of the oxide film 13 is reduced. If the material of the topmost surface of the oxide film 13 is SiO₂, it is necessary to protect the oxide film 13 by performing lithography thereon after the dry-etching. Consequently, the number of processes increases.

In addition, it is considered that wet-etching is performed without peeling off a resist used in performing dry-etching. However, after the dry-etching, the remaining resist is denatured by plasmas. Therefore, unless the remaining resist is subjected to ashing or the like, the remaining resist cannot be peeled off. If wet-etching is thus performed on the remaining resist without peeling off the remaining resist, it is necessary to perform, after the dry-etching, ashing to peel off the resist. Consequently, the part of the substrate, which part is in the element region 110, is oxidized by ashing. Accordingly, the property of the pass transistor is deteriorated. On the other hand, if a film whose material differs from SiO₂ is formed on the oxide film 13, the part of the substrate 9, which part is included in the element region 110, is protected by a part of the oxide film 11 even when the remaining resist is peeled off by ashing before the wet-etching upon completion of the dry-etching. Even if wet-etching is then performed, because the film whose material differs from SiO₂ is formed on the oxide film 13, the thickness of the oxide film 13 can be prevented from being reduced.

It is more preferable that SiN film is further formed on the oxide film 13. SiN is higher in permittivity than SiO₂. Thus the magnitude of an electric field generated at the interface between the block film and the gate electrode can be reduced. Due to this effect (“retarding effect”), electric-charge can be prevented from being exchanged between the charge storage film and the gate electrode through the block film. Consequently, the characteristics of the memory transistor are improved. In addition, if a buffered hydrofluoric acid is used as an etchant for wet-etching, only the oxide film made of SiO2 is selectively removed. Consequently, the thickness of the SiN film is substantially unchanged.

However, if ashing is performed to remove resist upon completion of dry-etching, the surface of the SiN film may be partly oxidized by plasmas. The hydrofluoric acid resistance of the oxidized part of the surface of the SiN film is weak. Thus, the oxidized part of the surface of the SiN film is removed by wet-etching. Consequently, the thickness of the SiN film is reduced. In such a case, preliminarily considering the above reduction of the thickness of the SiN film, it is advisable to form the SiN film having a larger thickness. Thus, the characteristic of the memory transistor can be prevented from being degraded. For example, assuming that a part having a depth of 2 nm from the surface of the SiN film would be oxidized by the ashing, and that a finally desired thickness of the SiN film is 3 nm, it is useful to form a SiN film having a thickness of 5 nm.

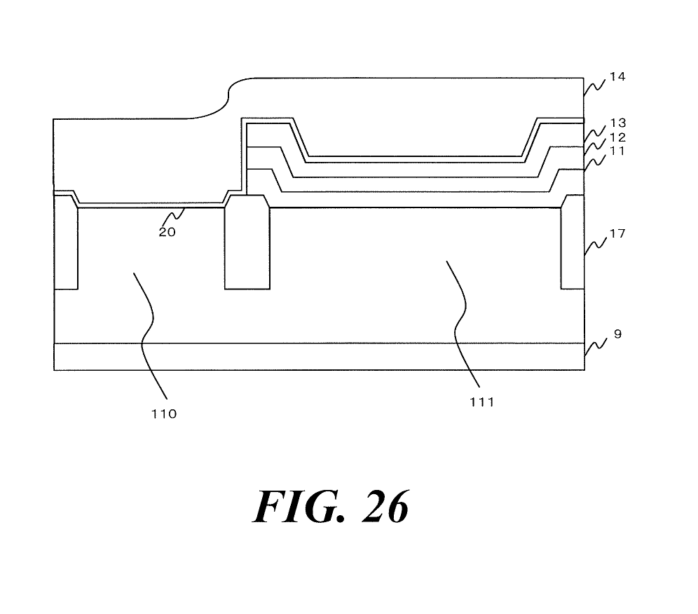

As illustrated in FIG. 26, after the oxide film 11, the nitride film 12 and the oxide film 13 are removed from the element region 110, a high-k film (i.e., high-permittivity film) 20 may be deposited on each of the element regions 110 and 111. Then, the gate electrode material may be deposited on the high-k film 20. The material of the high-k film 20 is an insulating material whose relative permittivity is larger than 7. Such a material is, e.g., Hf-oxide, Zr-oxide, Ta-oxide, Ti-oxide, La-oxide, Al-oxide and mixtures of such oxides, and LaAlO.

The properties of both of the pass transistor and the memory transistor can be improved by forming the high-k film 20. The EOT of the high-k film is thin. Therefore, as compared with the case of using SiO2 film as the gate insulating film, a current driving force can be increased with substantially equal amount of gate leakage current provided, using the high-k film as the gate insulating film of the pass transistor. In addition, the magnitude of the electric field generated at the interface between the block film and the gate electrode is reduced (what is called a retarding effect) by inserting the high-k film 20 into the block film of the memory transistor. Consequently, electric-charge can be prevented from being exchanged between the charge storage film and the gate electrode through the block film. Thus, the characteristics of the memory transistor are improved. FIG. 26 illustrates an example of forming the high-k film 20 after removing the oxide film 11, the nitride film 12 and the oxide film 13 from the element region 110. However, the high-k film may be formed after a SiO2 film is formed on the surface of the part of the substrate 9 at the element region 110, by oxidation, upon completion of removing the oxide film 11, the nitride film 12 and the oxide film 13 from the element region 110.

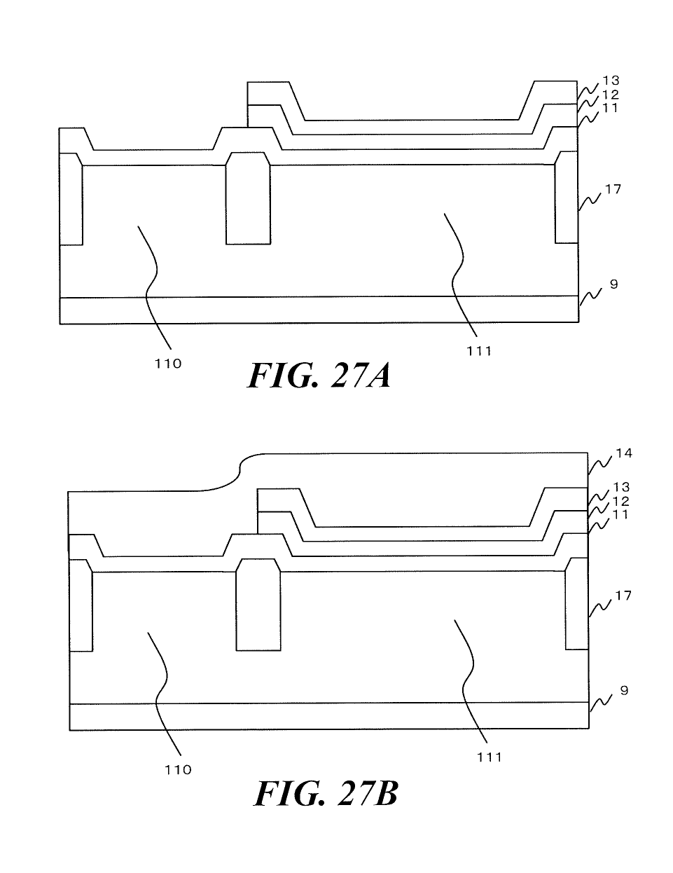

FIGS. 27A and 27B illustrate a process in the case of removing all of the oxide film 13 and the nitride film 12 in the element region 110 in which the pass transistor is formed, and leaving a part or all of the oxide film 11 unremoved so as to be used as the insulating film of the pass transistor. First, as illustrated in FIG. 27A, all of the oxide film 13 and the nitride film 12 in the element region 110 in which the pass transistor is formed, are removed. In addition, a part or all of the oxide film 11 is unremoved and used as the insulating film of the pass transistor. Then, as illustrated in FIG. 27B, the gate electrode material 14 is deposited on the films. In this case, the tunnel film of the memory transistor and the gate insulating film of the pass transistor can be manufactured simultaneously. Thus, the number of processes is small. Even in this case, etching may be performed utilizing only the dry-etching. Alternatively, etching may be performed utilizing only the wet-etching. Alternatively, the oxide film 13 and a part of the nitride film 12 may be etched by the dry-etching. The rest of the nitride film 12 may be etched by the wet-etching.

The advantages of the dry-etching and the wet-etching are as described above. In addition, if the wet-etching is used in the case of leaving a part or all of the oxide film 11 unremoved, etching can accurately be stopped at the boundary between two of the different films, because the logical switch excels in the selectivity for the etching of the oxide film 11, the nitride film 12 and the oxide film 13. Thus, variation of the thickness of each of the remaining films after the etching is performed is extremely small. The variation of the thickness of the gate insulating film of the pass transistor is small in a wafer.

After the etching is performed such that a part or all of the oxide film 13 of the element region 110 is left, the gate electrode material 14 is simultaneously deposited on the element regions 110 and 111. A material similar to the material used in the case of removing all of the oxide film 11, the nitride film 12 and the oxide film 13 of the element region 110 can be used as the gate electrode material.

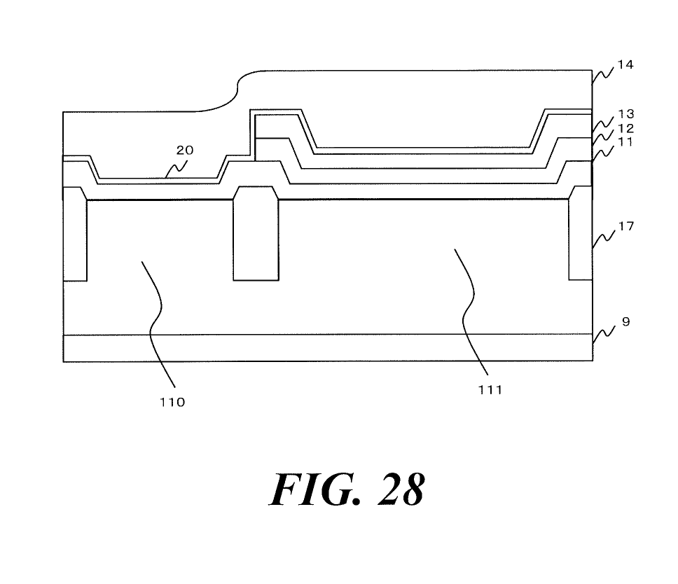

As illustrated in FIG. 28, after the etching is performed such that a part or all of the oxide film 11 is left, and before the gate electrode material is deposited, the high-k film 20 may be deposited on the element regions 110 and 111. A material similar to the material used in the case of removing all of the oxide film 11, the nitride film 12 and the oxide film 13 of the element region 110 can be used as the material of the high-k film 20.

In FIGS. 25A to 28, the case of depositing, after the STI is manufactured as illustrated in FIGS. 24A and 24B, the insulting film of the memory transistor has been described by way of example. However, as illustrated in FIG. 23, even in a case where the insulating film is deposited before the manufacture of the STI, the tunnel film, the charge storage film and the block film of the memory transistor and the gate insulating film of the pass transistor can be manufactured by a similar method as different films.

### (3) Processing of Gate Electrode and Gate Insulating Film

The oxide film 11, the nitride film 12, the oxide film 13 and the oxide film 18 are processed to thereby manufacture the gate electrode, the tunnel film, the charge storage film and the block film of the memory transistor, and the gate electrode and the gate insulating film of the pass transistor. Hereinafter, the tunnel film, the charge storage film and the block film of the memory transistor are generically as memory films.

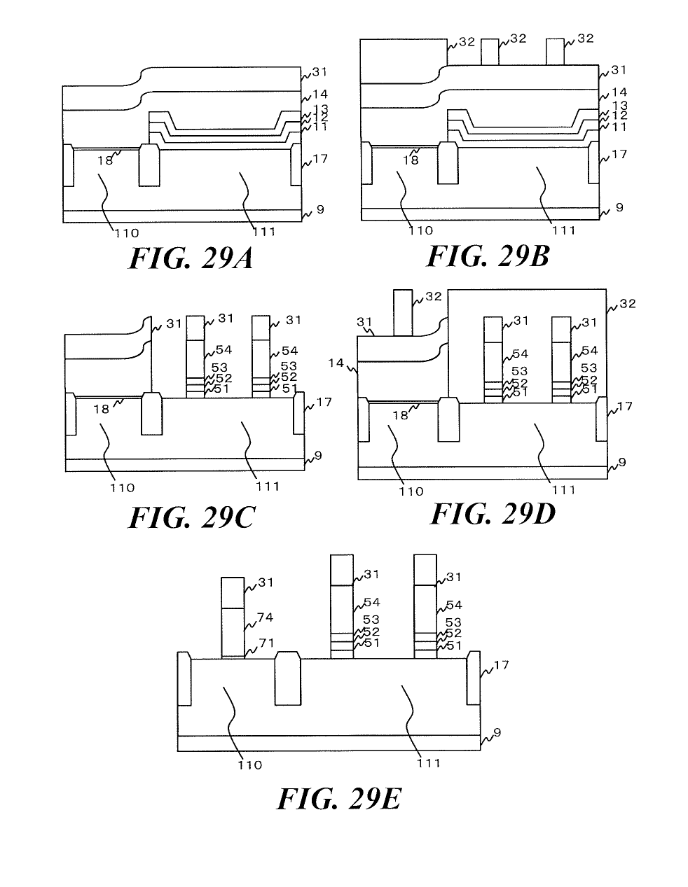

FIGS. 29A to 29E illustrate a first example of the process of processing the gate electrode, the gate insulating film and the memory films. In this example, the gate patterns of the memory transistors and the gate pattern of the pass transistor are lithographed independent of one another.

First, a mask material 31 is deposited on the gate electrode material 14 (see FIG. 29A). The mask material 31 is used in a case where the etching resistance of the resist in the etching of the gate electrode material is insufficient. The mask material 31 may be unnecessary if the etching resistance of the resist is excellent. If the gate electrode material 14 is, e.g., polysilicon, SiN is used as the mask material 31. Then, a resist 32 is applied onto the mask material 31. The gate pattern of the memory transistor is formed on the element region 111 by lithography (see FIG. 29B). At that time, the top portion of the element region 110 is protected by the resist 32. Then, the mask material 31, the gate electrode material 14, the oxide film 13, the nitride film 12 and a part or all of the oxide film 11 of the element region 111 are etched using the resist 32 as a mask (see FIG. 29C). This etching may be performed by dry-etching. Alternatively, the mask material 31, the gate electrode material 14, the oxide film 13 and the nitride film 12 may be etched by dry-etching, while a part or all of the oxide film 11 may be etched by wet-etching. The tunnel film 51, the charge storage film 52, the block film 53 and the gate electrode 54 are formed by this etching. Depending on the degree of etching, the charge storage film 52 may be connected in each memory transistor. Alternatively, the charge storage film 52 may be divided, as illustrated in FIG. 29C. Then, the resist 32 is applied onto the materials, the films and the element region. The gate pattern of the pass transistor is formed on the element region 110 by lithography (FIG. 29D). At that time, the top portion of the element region 111 is protected by the resist 32. Then, the mask material 31, the gate electrode material 14 and a part of all of the insulating film 18 on the element region 110 are etched using the resist 32 as a mask (see FIG. 29E). A gate insulating film 71 and a gate electrode 74 of the pass transistor are formed by this etching. The processing of the memory transistor may be performed after the processing of the pass transistor.

If the gate pattern of the memory transistor and the gate pattern of the pass transistor are processed by being lithographed, similarly to the first example, conditions for exposure at the time of lithographing of the memory transistors and the pass transistor can be adjusted independent of one another. As described above, in the case of collectively lithographing the gate pattern of the memory transistor and the gate pattern of the passing transistor, it is necessary for reducing the influence of the difference in height between the element regions 110 and 111 to determine a focus height for exposure. In the case of performing exposure of minute gate patterns, a finished pattern is affected by a slight difference in height from the substrate. Optimum exposure of each element region can be performed by adjusting exposure conditions at the time of lithographing of the memory transistors and the pass transistor. Devices can be processed to designed dimensions.

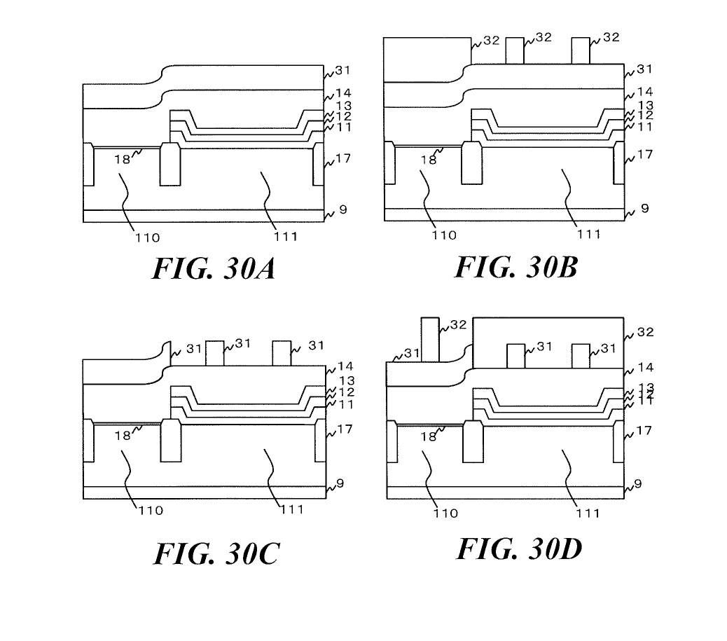

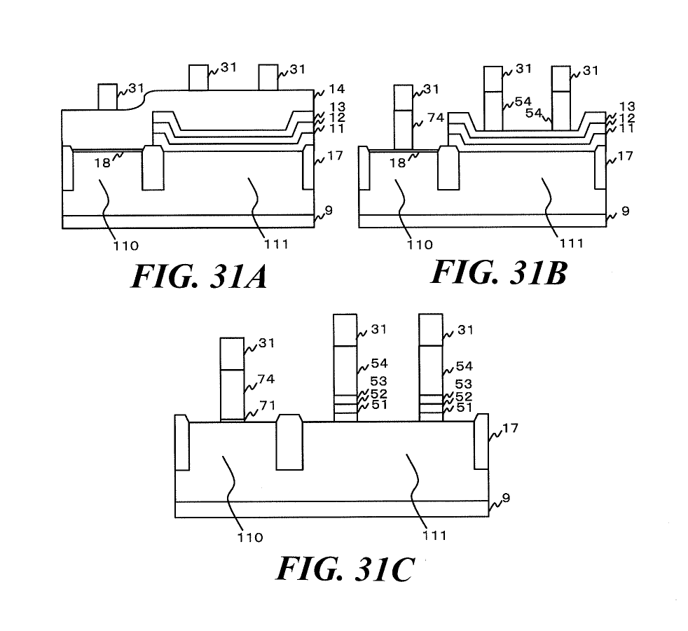

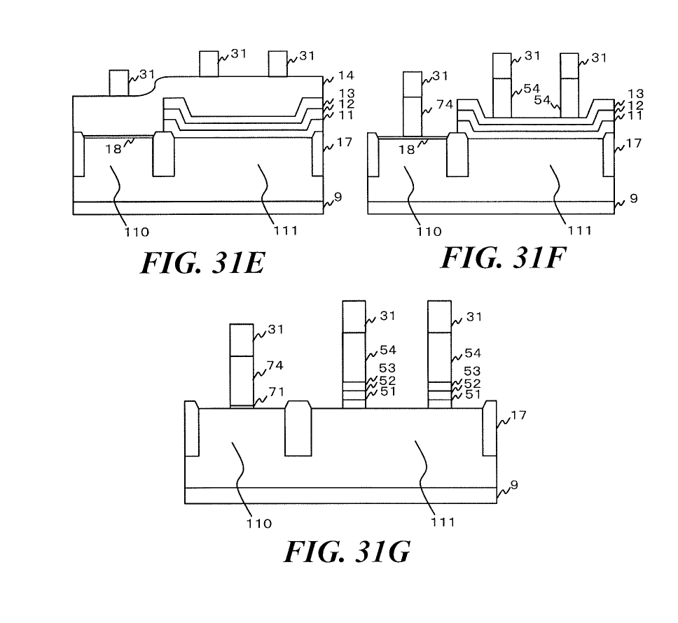

A second example of a process of processing the gate electrode, the gate insulating film and memory films is described hereinafter with reference to FIGS. 30A to 30D and 31A to 31C. In this example, the gate pattern of each memory transistor and the gate pattern of the pass transistor are lithographed independent of one another. In addition, mask materials are processed independent of one another. However, the processing of the gate electrode material 14 into the gate electrode of each memory transistor is performed simultaneously with the processing of the gate electrode material 14 into the gate electrode of the pass transistor.

Similarly to the first example, in the second example, first, the mask material 31 is deposited (see FIG. 30A). Then, a resist 32 is applied onto the mask material 31. A gate pattern of each memory transistor is formed on the element region 111 by lithography (see FIG. 30B). At that time, the top portion of the element region 110 is protected by the resist 32. In the second example, it is indispensable to deposit the mask material 31. The mask material 31 is etched using the resist 32 as a mask (see FIG. 30C). Then, a gate pattern of the pass transistor is formed at the top portion of the element region 110 by lithography by applying the resist 32 (see FIG. 30D). At that time, the top portion of the element region 111 is protected by the resist 321. Then, the mask material 31 on the element region 110 is etched using the resist 32 as a mask (see FIG. 31A). The processing of the mask material 31 on the element region 111 may be performed after the processing of the mask material 31 on the element region 110.

Then, the gate electrode material 14 on the element regions 110 and 111 are collectively etched using the mask material 31 as a mask (see FIG. 31B). Next, the insulating film 18 on the element region 110 and the oxide film 13, the nitride film 12 and the oxide film 11 on the element region 111 are etched using the mask material 31 as a mask. Thus, the gate electrode, the memory films and the gate insulating film can be processed, as illustrated in FIG. 31C. This etching may be dry-etching. Alternatively, the mask material 31, the gate electrode material 14, the oxide film 13 and the nitride film 12 may be etched by dry-etching, while a part or all of the oxide film 11 may be etched by wet-etching. However, in order to reduce an amount of a part of the substrate surface at the element region 110, it is necessary to select an appropriate gas.

Similarly to the first example, even in the second example, the gate pattern of each memory transistor and the gate pattern of the pass transistor are processed in different steps by being lithographed. Thus, exposure conditions for lithographing each memory transistor and the pass transistor can be adjusted independent of one another. A device can be processed to dimensions as designed. In the first example, in a step illustrated in FIG. 29C, bump-like portions are generated in the element region 111, whose thickness is substantially equal to a sum of thicknesses of the memory films, the gate electrode material 14 and the mask material 31. In a step illustrated in FIG. 29D, the application of a resist having a sufficient thickness to the mask material 31 on the element region 111 may fail. In addition, the applied resist may be insufferable to the etching of the mask material. On the other hand, in the case of the second example, bump-like portions generated in the element region 111 in a step illustrated in FIG. 30C has a thickness that is substantially equal to the thickness of the mask material 31. Thus, a sufficient amount of resist sufferable to the etching of the mask material can be applied onto the element region and the like.

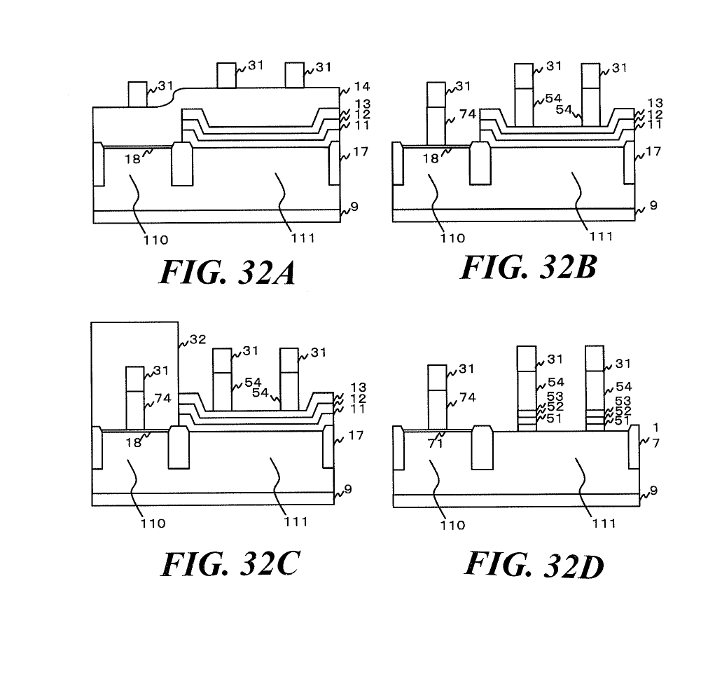

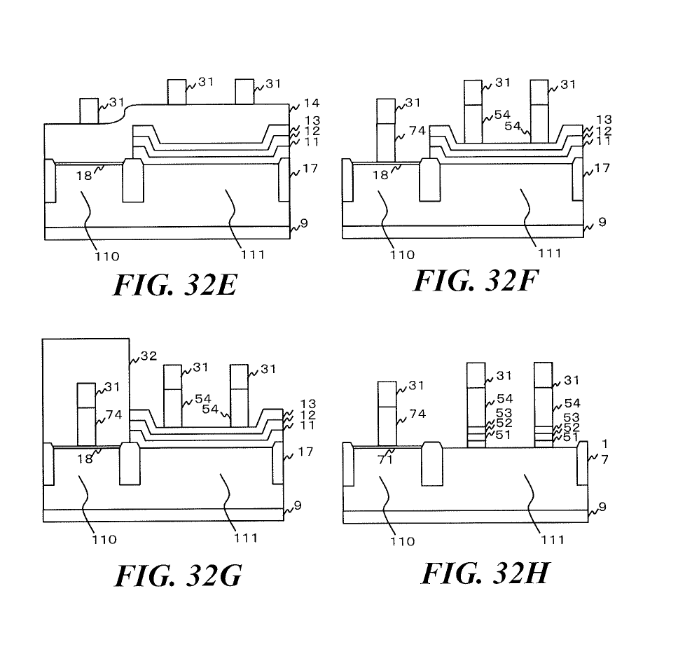

FIGS. 32A to 32D illustrate a process according to a modification of the second example. In this modified process, steps up to a step illustrated in FIG. 32B are similar to the steps illustrated in FIGS. 30A to 31B of the process according to the second example. In a state illustrated in FIG. 32B, the resist is applied to the element region 110. Thus, the element region 110 is protected by the resist, as illustrated in FIG. 32C. Then, as illustrated in FIG. 32D, the oxide film 13, the nitride film 12, the oxide film 11 on the element region 111 are etched using the mask material 31 as a mask. Consequently, as compared with the second example, the number of times of performing lithographing is increased by 1. However, when the oxide film 13, the nitride film 12 and the oxide film 11 on the element region 111 are etched, the substrate surface at the element region 110 can be prevented from being etched. If the part of the substrate surface at the element region 110, is etched, the parasitic resistance of the channel of the pass transistor becomes high. This leads to reduction of the speed of the logic switch.

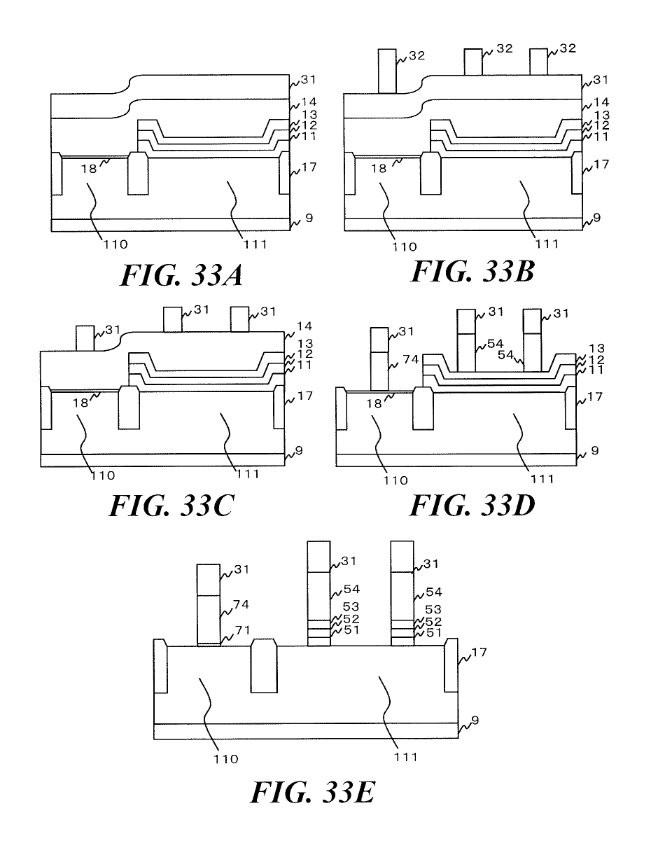

A third example of the process of processing the gate electrode, the gate insulating film and the memory film is described hereinafter with reference to FIGS. 33A to 33E. According to the third example, patterning is performed by the same lithography-process to produce the gate pattern of the memory transistor and the gate pattern of the pass transistor. In addition, the mask material on the element region 110 and the mask material on the element region 111 are simultaneously processed. The gate electrode material on the element region 110 and the gate electrode material on the element region 111 are simultaneously processed.

Similarly to the second example, in the third example, the mask material 31 is deposited (see FIG. 33A). Then, the resist 32 is applied onto the mask material 31. The gate pattern of each memory transistor is formed on the element region 111 by lithography. The gate pattern of the pass memory transistor is formed on the element region 110 by lithography (FIG. 33B). Then, the mask material on the element regions 110 and 111 are etched using the resist 32 as a mask (see FIG. 33C). After that, the gate electrode materials 14 on the element regions 110 and 111 are collectively etched using the mask material 31 as a mask (see FIG. 33D). Then, the insulating film 18 on the element region 110 and the oxide film 13, the nitride film 12 and the oxide film 11 on the element region 111 are etched using the mask material 31 as a mask. Thus, the material is processed into the gate electrode, the memory films and the gate insulating film, as illustrated in FIG. 33E. This etching may be dry-etching. Alternatively, the mask material 31, the gate electrode material 14, the oxide film 13 and the nitride film 12 may be etched by dry-etching, while a part or all of the oxide film 11 and the insulating film 18 may be etched by wet-etching. However, in order to reduce an amount of a part of the substrate surface to be etched at the element region 110, it is necessary to select an appropriate etching gas.

In the case of the process according to the third example, the number of times of performing lithography is 1. As compared with the first example, the second example and a modification, the number of times of performing lithography is small. Thus, the manufacturing cost can be reduced. In the process according to the third example, patterning is performed so that the gate patterns of the memory transistors and the pass transistor are generated in the same lithography process. At that time, the element region 110 differs from the element region 111 in the height of the wafer. However, in the case of using a MONOS structure as each memory transistor, the difference in the height of a wafer is about 20 nm. Thus, patterns having dimensions as designed can be formed by selecting exposure conditions that reduce the influence of the difference in height. Alternatively, the influence of the difference in height may be reduced by preliminarily applying, before the resist is applied, an organic film, a coating-type silicon insulating film, or the like onto the mask material 31 as a resist base film.

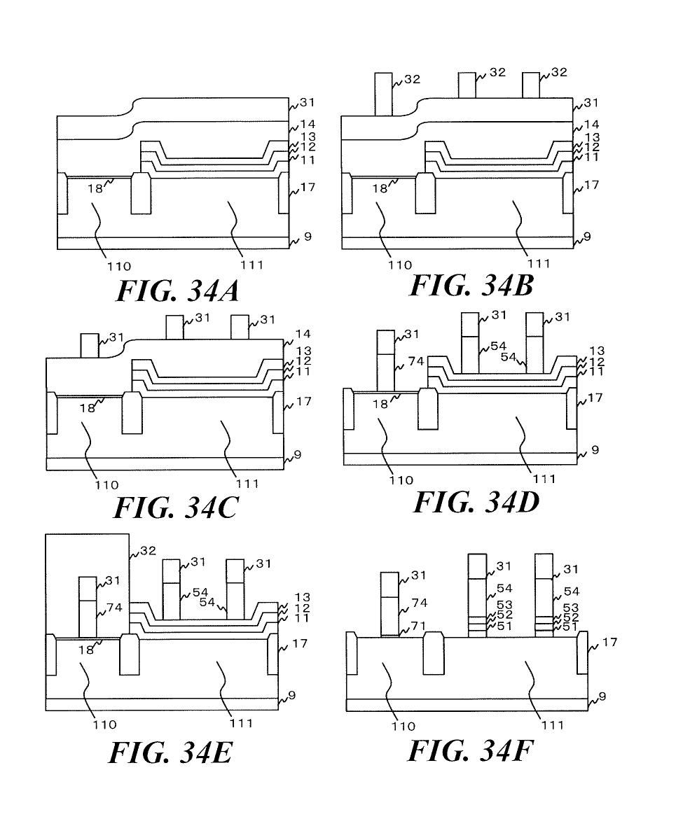

FIGS. 34A to 34F illustrate a process according to a modification of the third example. In this modified process, steps illustrated in FIG. 34A to 34F are similar to the steps illustrated in FIGS. 33A to 33D of the process according to the third example. In a state illustrated in FIG. 34D, the resist is applied to the element region 110. Thus, the element region 110 is protected by the resist. Then, as illustrated in FIG. 34F, the oxide film 13, the nitride film 12, the oxide film 11 on the element region 111 are etched using the mask material 31 as a mask.

Consequently, as compared with the third example, the number of times of performing lithographing is increased by 1. However, when the oxide film 13, the nitride film 12 and the oxide film 11 on the element region 111 are etched, the substrate surface at the element region 110 can be prevented from being etched. As compared with the modification of the second example, the number of times of performing lithographing is decreased by 1. As compared with the first example, the number of times of performing lithographing is unchanged. However, in the lithographing process illustrated in FIG. 34E, microscopic patterning is unnecessary. Therefore, the lithographing process illustrated in FIG. 34E does not require a high-cost process such as a liquid immersion process. When the lithographing process illustrated in FIG. 34E is performed, in the wafer, bump-like portions are generated, whose thickness is substantially equal to a sum of thicknesses of the mask material and the gate electrode material. However, because the lithographing process illustrated in FIG. 34E does not require microscopic patterning, even when the thickness of the resist is increased, each pattern can be formed to dimensions as designed. Accordingly, in consideration of bump-like portions produced in the wafer, it is advisable to preliminarily apply the resist thickly.

In the above first to third examples and the modifications thereof, when the gate electrode material is processed by dry-etching using the mask material as a mask, ashing is performed to eliminate residue. At that time, if polysilicon is used as the gate electrode material, a side surface of the gate electrode is oxidized. In a state in which the side surface of the gate electrode is oxidized, if the etching of the oxide film 13, the nitride film 12 and the oxide film 11 is performed at two stages, respectively corresponding to dry-etching and wet-etching, the oxide film 13, the nitride film 12 and the oxide film 11, on the element region 111 are processed and formed into the shape of the gate electrode including the oxide film provided on the side surface. On the other hand, at the time of performing wet-etching, the oxide film provided on the side surface of the gate electrode is removed. Thus, the cross-sectional area in a (horizontal) direction parallel to the substrate of the gate electrode is size smaller than that in such a direction of the memory film. In this state, the controllability of the memory transistor on the basis of the gate voltage is low.

Even if the oxide film 13, the nitride film 12 and the oxide film 11 on the element region 111 are etched only dry-etching in a state in which the side surface of the gate electrode is oxidized, the oxidized side surface of the gate electrode is not removed. The oxidized portion of the side surface of the gate electrode does not function as an electrode. Therefore, the controllability of the memory transistor on the basis of the gate voltage is poor.

Thus, according to the first to third examples and the modifications thereof, after the gate electrode material of the memory transistor or the gate electrode materials of both of the memory transistor and the pass transistor is processed by dry-etching using the mask material as a mask, and before the oxide film 13 on the element region 111 is etched, wet-etching is performed using a solution including a hydrofluoric acid. Consequently, the oxide film 13 on the element region 111 can be etched after the oxide film on the side surface of the gate electrode is removed. Thus, the shape of the cross-section in the (horizontal) direction parallel to the substrate of the memory film is extremely close to the shape of the cross-section in the (horizontal) direction parallel to the substrate of the gate electrode.

In the above description made with reference to FIGS. 29A to 29E and 34A to 34F, examples of the case of depositing, after the STI is manufactured as illustrated in FIGS. 24 and 24B, an insulating film of the memory transistor has been described. However, even in the case of depositing, before the STI is manufactured, as illustrated in FIGS. 23A to 23E, an insulating film of the memory transistor, the gate electrode and the gate insulating film can be processed in similar methods.

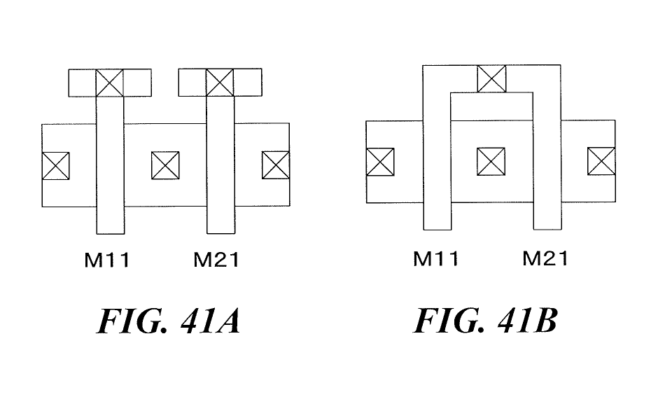

However, in the case of depositing, after the STI is manufactured, the insulating film of the memory transistor, it is necessary to layout the memory transistors M11 and M21 such that the gate electrodes of the memory transistors M11 and M21 are separated from each other, as illustrated in FIG. 41A. In this case, each of the gate electrode of the memory transistor M11 and the gate electrode of the memory transistor M21 is electrically connected to a wire other than the gate electrode material. If the memory transistors M11 and M21 share the gate electrode, as illustrated in FIG. 41B, the charge storage film 52 of the memory transistor M11 and the charge storage film 52 of the memory transistor M21 are electrically connected to each other. In this case, electrons injected into the charge storage film 52 of the memory transistor M11 may move to the charge storage film 52 of the memory transistor M21. In addition, threshold voltage of the memory transistor M21 may be changed. Especially, if an electrically conductive material, such as a Si-rich SiN film or a doped polysilicon, is used as the material of the charge storage film, because electrons easily move in the charge storage film, it is indispensable to layout the device such that the gate electrodes of the memory transistors M11 and M21 illustrated in FIG. 41A are separated from each other.

### (4) Wiring

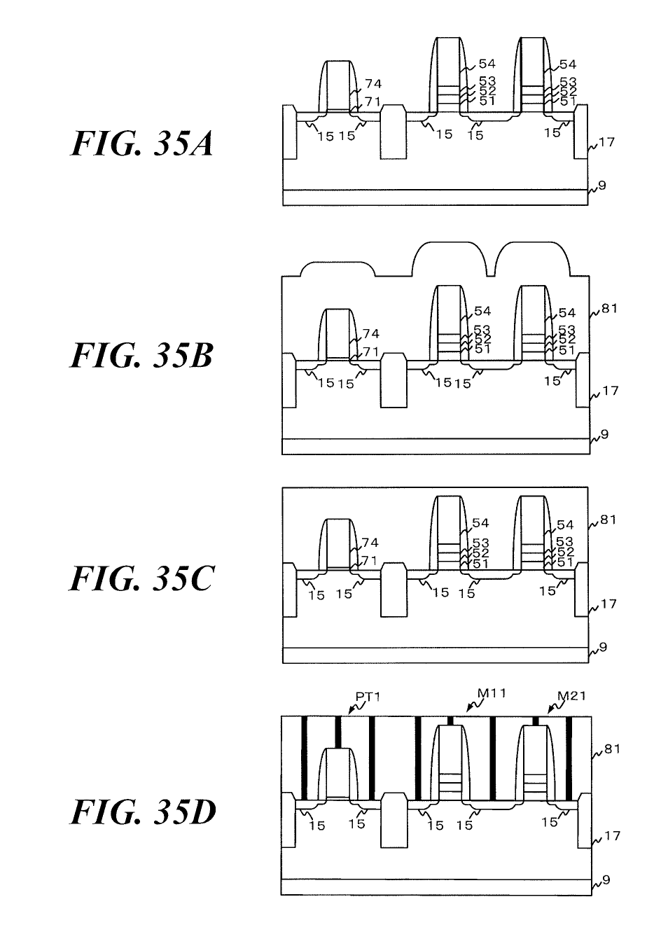

FIGS. 35A to 35D illustrate a wiring process. Upon completion of processing the gate electrodes 54, 74, the gate insulating film 71, the tunnel film 51, the charge storage film 52 and the block film 53, ions for the sources/drain electrodes of the memory transistors M11 and M21 and the pass transistor PT1 are injected thereto (see FIG. 35A) and an interlayer insulating film 81 is deposited (see FIG. 35B) using the gate electrodes 54 and 74 and a gate side surface material as masks. The material of the interlayer insulating film 81 is SiN, SiO₂, or the like. If the height of the surface of the gate electrode of each of the pass transistor and the memory transistors from the surface of the substrate has a some value, a bump-like option may be formed on the surface of the interlayer insulating film 81. Because the subsequent lithography for forming contacts is microscopic patterning, if there is an uneven part on the surface of the interlayer insulating film 81, the microscopic patterning cannot be performed. Thus, in order to eliminate an uneven part on the surface of the inter layer insulting film, planarization based on e.g., chemical mechanical polishing (CMP) processing is performed. The CMP processing is performed in a temporally control method.

Usually, in the case of manufacturing chips on each of which transistors being equal or close to one another in thickness of the gate insulating film are mixedly mounted, the CMP processing of the interlayer insulating film of each transistor is performed until the gate electrode thereof is exposed. Then, the CMP processing is stopped by detecting that the gate electrode is exposed. However, according to the present embodiment, the memory film of each memory transistor differs from the gate insulating film of the pass transistor in thickness. Thus, the memory transistors and the pass transistor differ from one another in height of the surface of the gate electrode from the surface of the substrate. Accordingly, as the CMP processing proceeds, a timing at which the gate electrode of the memory transistor is exposed may differ from a timing at which the gate electrode of the pass transistor is exposed. Thus, an error may occur in the detection of the exposure of the gate electrode. Hence, the planarization processing can be performed with high controllability by performing the CMP processing in a temporally control method.

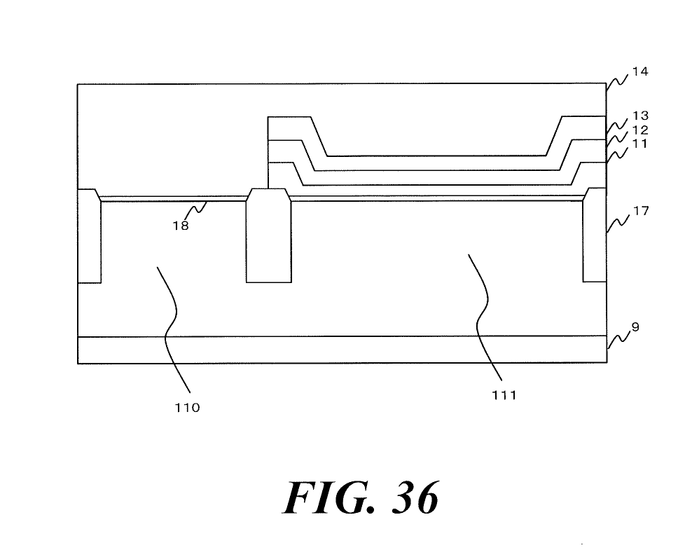

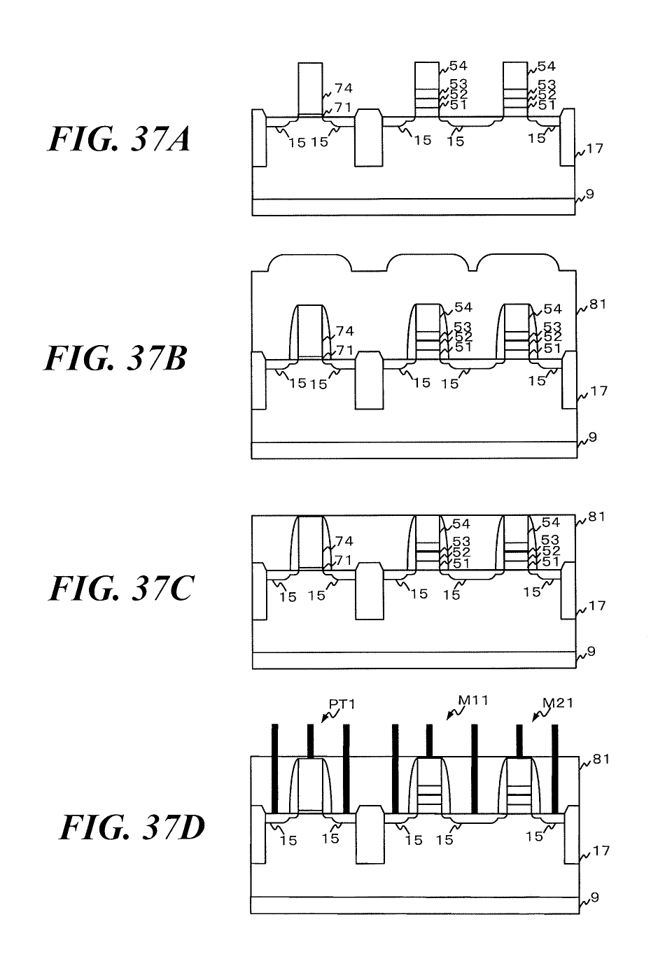

The surface of the gate electrode 14 may be planarized by CMP, as illustrated in FIGS. 36A to 36D, after the gate electrode materials 14 are deposited (e.g., after the process illustrated in FIG. 25B). If the surface of the gate electrode material is preliminarily planarized, the heights of the surfaces of the memory transistors and the pass transistors from the surface of the substrate are uniformized, as illustrated in FIG. 37A. Therefore, as illustrated in FIG. 37C, the CMP processing can be stopped by detecting the exposure of the gate electrode. In addition, in a case where the gate patterns of the memory transistor and the pass transistor are formed in the same lithography process as described in the description of the third example of the process for processing the gate electrode, the gate insulting film and the memory films, bump-like portions are not generated on the element regions 110 and 111 by preliminarily planarizing the surfaces of the gate electrodes 14. Consequently, patterning is performed to generate gate patterns according to optimal exposure conditions for both of the memory transistor and the pass transistor.

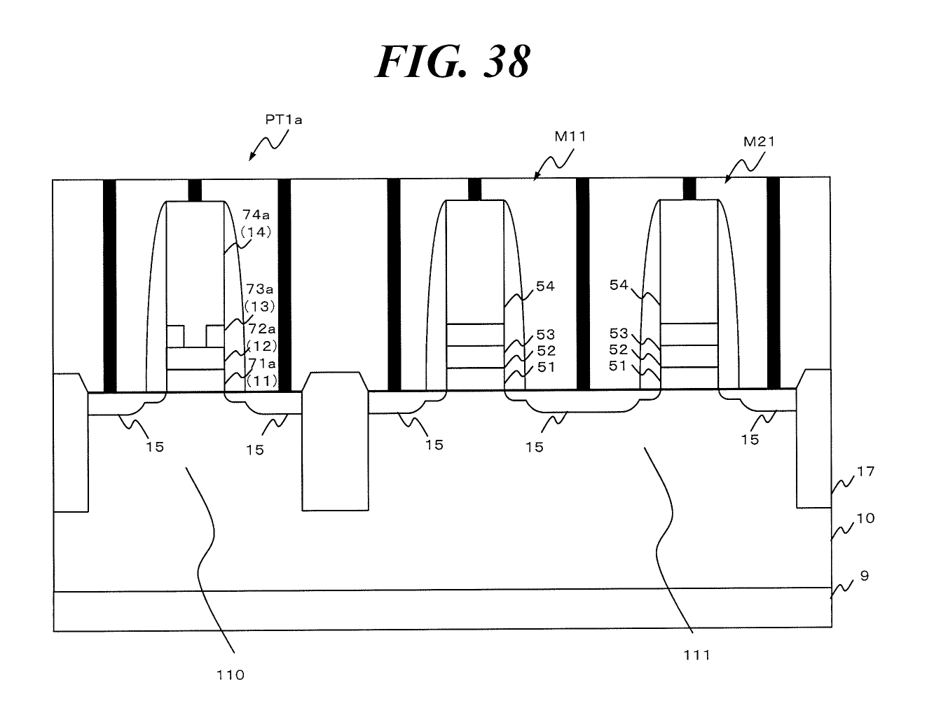

Even in the case of manufacturing the pass transistor PT1A as illustrated in FIG. 38, the top surfaces of the gate electrodes of the pass transistor and the memory transistor are equalized in height from the surface of the substrate. The pass transistor illustrated in FIG. 38 is formed by depositing, on the element regions 110 and 111, the oxide film 11, the nitride film 12 and the oxide film 13, then forming a hole penetrating through the oxide film 13 of the element region 110 such that the surface of the nitride film 12 is exposed from the hole, then depositing the gate electrode material 14 so as to fill the hole, and to bring the gate electrode material 14 and the nitride film 12 into contact with each other. Alternatively, the pass transistor is formed by depositing, on the element regions 110 and 111, the oxide film 11, the nitride film 12 and the oxide film 13, then forming a hole penetrating through the oxide film 13 of the element region 110 such that the surface of the oxide film 11 is exposed from the hole, then depositing the gate electrode material 14 so as to fill the hole, and to bring the gate electrode material 14 and the oxide film 11 into contact with each other.

### Second Embodiment

In a logic switch according to a second embodiment, the channel width W1 of one of the memory transistors included in a cell is larger than the channel width W2 of the other memory transistor. In the second embodiment, for example, the cell 1b illustrated in FIG. 2 is assumed. A bit line connected to the memory transistor having the channel width W1 is connected to a ground voltage during an operation thereof. A bit line connected to the memory transistor having the channel width W2 is connected to a power-supply voltage during an operation thereof.

Hereinafter, a description is made by assuming that the memory transistor M11 connected to the bit line BL1 is larger in channel width than the memory transistor M21 connected to the bit line BL2. During an operation, the bit line BL1 is connected to the ground voltage, and the bit line BL2 is connected to the power-supply voltage.

In order to prevent occurrence of a malfunction of the pass transistor during an operation of the logic switch, a voltage at the node Q is fixed to the ground voltage, or to the power-supply voltage. For example, if the signal level of, e.g., a signal input to the source or drain of the pass transistor is changed from a high level (H) to a low level (L), or if the signal level of, the signal input to the source or drain of the pass transistor is changed from L to H, a fluctuation occurs of the voltage at the node Q due to the capacitive coupling between the source/drain and the gate thereof.

Usually, even when a fluctuation of the voltage at the node Q occurs, current flows through one of the memory transistor M11 and the memory transistor M21 which is in an erased state. Thus, the voltage at the node Q returns to the ground voltage or to the power-supply voltage. A time taken to return the voltage at the node Q thereto depends upon an amount of current flowing through the memory transistor. Therefore, preferably, the channel width of the memory transistor is large. However, if the channel width is increased, a chip area increases.

Thus, an operation condition of the cell 1b in the case of causing a fluctuation of the voltage at the node Q is studied hereinafter by classifying the operation condition into four sub-conditions.

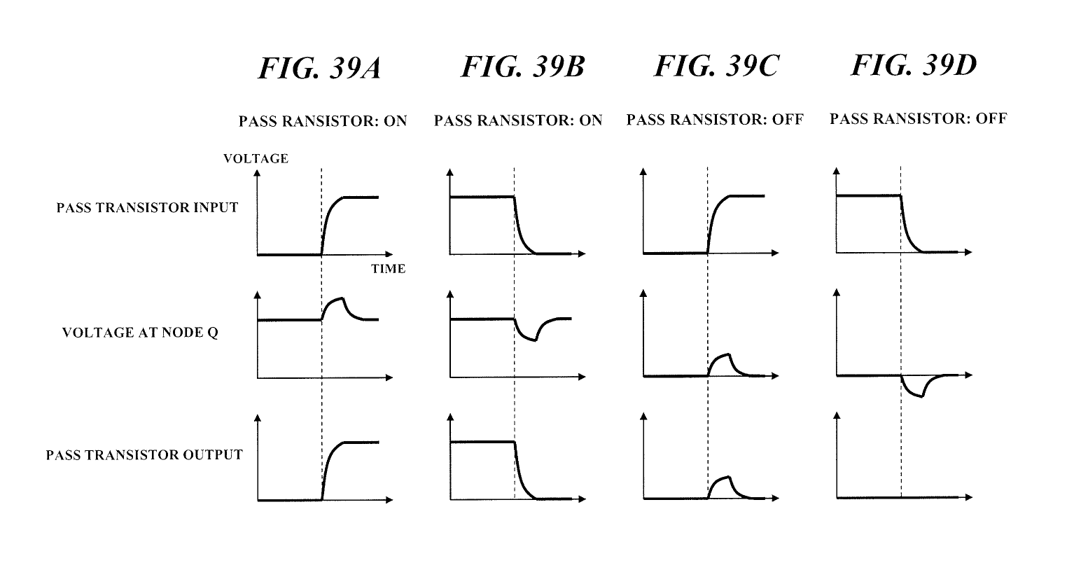

FIG. 39A illustrates a first condition. In the first condition, the memory transistor M11 is in a written state, that the memory transistor M21 is in an erased state, and that the level of the input signal to the pass transistor PT1 is changed from L to H. If the level of the input signal to the pass transistor PT1 is changed from L to H, the voltage at the node Q fluctuates in a rising direction in which the voltage at the node Q rises. However, at that time, the pass transistor PT1 is in an on-state. Therefore, even when the voltage at the node Q fluctuates in the rising direction, the on/off state of the pass transistor is unchanged.

FIG. 39B illustrates a second condition. In the second condition, the memory transistor M11 is in a written state, that the memory transistor M21 is an erased state, and that the signal level of an input signal to the pass transistor PT1 is changed from H to L. If the level of the input signal to the pass transistor PT1 is changed from H to L, the voltage at the node Q fluctuates in a falling direction in which the voltage at the node Q falls. At that time, the pass transistor PT1 is in an on-state. Due to the drop of the voltage at the node Q, the state of the pass transistor PT1 may change to an off-state momentarily. However, the level of a signal to be passed through the pass transistor PT1 is L. In a case where the pass transistor PT1 is an N-type transistor, generally, the N-type transistor allows a signal whose level is L, if the gate voltage thereof is equal to or higher than a threshold value. Therefore, even if the state of the pass transistor PT1 changes to an off-state momentarily, the signal whose level is L can go through the pass transistor PT1. Thus, a malfunction of the logic switch does not occur.

FIG. 39C illustrates a third condition. In the third condition, the memory transistor M11 is in an erased state, that the memory transistor M21 is in a written state, and that the level of an input signal to the pass transistor PT1 is changed from L to H. At that time, the pass transistor PT1 is in an off-state. However, the voltage at the node Q fluctuates in a rising direction in which the voltage at the node Q rises. Thus, the state of the pass transistor PT1 may change to an on-state momentarily. Therefore, a signal which has a level H and should not be allowed to pass through the pass transistor T1 may pass therethrough. Accordingly, a malfunction of the logic switch does not occur.

FIG. 39D illustrates a fourth condition. In the fourth condition, the memory transistor M11 is in an erased state, that the memory transistor M21 is in a written state, and that the signal level of an input signal to the pass transistor PT1 is changed from H to L. At that time, the pass transistor is in an off-state. Thus, even in a case where the voltage at the node Q fluctuates in a falling direction, the on/off state of the pass transistor PT1 is unchanged.

As described above, it is the third condition that may cause a malfunction of the logic switch. In the third condition, the memory transistor M11 is in an erased state, while the memory transistor M21 is in a written state. This condition corresponds to a state in which the ground voltage is supplied to the node Q via the memory transistor M11. Thus, the driving force is enhanced by increasing the channel width of the memory transistor M11, so that when the voltage at the node Q fluctuates in the third condition, a time taken to return the voltage at the node Q can be reduced.

On the other hand, in the first, second and fourth conditions, even if the voltage at the node Q fluctuates, an operation of the logic switch is not affected by the fluctuation of the voltage at the node Q. Thus, the driving force of the memory transistor M21 is permitted to be smaller than the driving force of the memory transistor M11. Hence, the channel width W2 of the memory transistor M21 is set to be smaller than the channel width W1 of the memory transistor M11. Consequently, occurrence of a malfunction of the logic switch can be prevented while increase of the chip area is suppressed.

Even if the pass transistor PT1 is a P-type transistor, the logic switch according to the present embodiment has similar advantages. In a case where the memory transistor M11 is in a written state, and where the memory transistor M21 is in an erased state, the state of the pass transistor PT1 may change to an on-state momentarily. Therefore, if the pass transistor PT1 is a P-type transistor, the channel width of the memory transistor M21 is increased, and the channel width of the memory transistor M11 is set to be smaller than the channel width of the memory transistor M21. Consequently, occurrence of a malfunction of the logic switch can be prevented while increase of the chip area is suppressed.

It is clarified by referring to computer aided design (CAD) drawings used to design a mask for lithographing that the designed values of the channel widths W1 and W2 differ from each other. Generally, after the layout of patterns is performed, correction such as optical proximity correction (OPC) is performed. However, uncorrected CAD drawings are used to check the designed values of the channels widths.

In the actual manufacture of devices, there is variation of the channel width of processed devices due to the influence of variations caused by lithography apparatuses, variations caused by resists and variations caused by base films formed on wafers. According to, e.g., International Technology Roadmap for Semiconductors (ITRS) 2009, it has been proposed, in consideration of all causes of the above variations, that the variations of pattern sizes should be suppressed so that “3*σ” (σ: a standard deviation) is within 10% of a size average. Accordingly, assuming that an average value of the channel width W1 in a chip is designated with “W1(ave)”, and that an average value of the channel width W2 in a chip is designated with “W2(ave)”, if the difference between the average values W1(ave) and W2(ave) is small, the difference therebetween may be buried in the variation thereof. However, the average value W1 is equal to or more than 10% of the average value W2(ave), the advantage in preventing a malfunction of the logic switch is promised.

The values W1(ave) and W2(ave) can be obtained by opening the manufactured chip and observing the shapes of gate electrodes with an electronic microscope or the like.

Setting the channel widths W1 and W2 at different values enables a verify operation for checking whether write operations have been performed on individual memory transistors. According to the present embodiment, verify-operations are performed by applying a predetermined verify-voltage to the word line WL1 and checking the value of the resistance between the bit lines BL1 and BL2.

When both the memory transistors M11 and M21 are in an erased state, the resistance between the bit lines BL1 and BL2 is low. On the other hand, when data is written to one of the memory transistors M11 and M21 so as to largely change a channel resistance, the resistance between the bit lines BL1 and BL2 becomes substantially equal to the channel resistance of the memory transistor to which data has been written. If the memory transistors M11 and M21 have the same structure, it cannot be determined from the resistance value between the bit lines which of the memory transistors the data has been written to. In the present embodiment, the channel widths W1 and W2 are set at different values, so that a difference in the channel resistance of the memory transistors is caused between a written state and an erased state. Therefore, it can be determined which of the memory transistors the data has been written to.

In order to achieve the verify-operations, the channel width W1 should be set to be larger than the channel width W2 in all logic cells. The variation of the pattern sizes in the manufacture of devices is considered to be within 10%. If the difference between the average values W1(ave) and W2(ave) is equal to or more than 20% in consideration of both the variation of the channel width W1 and the variation of the channel width W2, a verify-operation can be achieved.

In order to enable a verify-operation, a method of setting the gate length of the memory transistor M11 and the gate length of the memory transistor M21 at different values, and a method of setting each of the gate length and the channel width of the memory transistor M11 at a value differing from the value of an associated one of the gate length and the channel width of the memory transistor M21 are also considered. However, in this case, the threshold voltage Vth of a transistor depends upon the gate length thereof. Therefore, if the memory transistors M11 and M21 differ from each other in gate length, the threshold voltage Vth and the voltage VDsat which corresponds to occurrence of the channel pinch-off vary with individual transistors. Thus, it is necessary to change a write voltage according to which of the transistors data is written to. This means that a large number of power-supply voltages should be prepared. This results in a increase of cost. On the other hand, the method of changing the channel width between the memory transistors as described in the present embodiment affects neither the threshold voltages Vth nor the voltage VDsat. Thus, the same write voltage can be used, regardless of which of the memory transistors the data is written to.

The present embodiment has been described by assuming that the channel width of the memory transistor M11 is larger than the channel width of the memory transistor M21. However, while the logic switch operates, if the bit line BL2 is connected to the ground voltage and the bit line BL1 is connected to the power-supply voltage, the channel width of the memory transistor M21 is set to be larger than the channel width of the memory transistor M11.

The writing method and the erasure method described in the first embodiment can be used as the writing method and the erasure method in the second embodiment. In addition, the charge storage film and the block film that satisfy the requirements described in the first embodiment can be used as the charge storage film and the block film according to the second embodiment, respectively.

According to the embodiments, data can be selectively written to the memory transistor such that the threshold voltage Vth thereof is at a high level. In addition, back-tunneling can be prevented from occurring when data is erased from the memory transistor. That is, according to the embodiments, a programmable logic switch which has a small chip area and which can perform writing and erasing data without causing a malfunction can be accomplished. Further, the influence of a fluctuation of the voltage at the node Q caused when an input signal to the pass transistor changes can be reduced, and a malfunction of the programmable logic switch can be prevented, while an increase of the chip area is suppressed.

1. A semiconductor integrated circuit, comprising:
a substrate;
a plurality of nonvolatile memory portions formed in the substrate, each nonvolatile memory portion including
a first nonvolatile memory having a control gate, and
a second nonvolatile memory having a control gate connected to the control gate of the second nonvolatile memory; and
a plurality of logic transistor portions formed in the substrate, each logic transistor portion including
at least one of logic transistor,
wherein the logic transistors include:
a first transistor which is directly connected to drains of the first and second nonvolatile memories at its gate; and
a second transistor which is not directly connected to the drains of the first and second nonvolatile memories, and
wherein, among the logic transistors, a bottom surface of the gate of each of the transistors sandwiching the first and second nonvolatile memories is lower in height from a top surface of the substrate than a bottom surface of the control gate of each of the first and second nonvolatile memories.

2. The semiconductor integrated circuit of claim 1, further comprising:
an element isolation region,
wherein only one of the element isolation region is provided between the first nonvolatile memory and the first transistor adjacent to the first nonvolatile memory.

3. The semiconductor integrated circuit of claim 1,
wherein a minimum distance between the first nonvolatile memory and the first transistor adjacent to the first nonvolatile memory is equal to or less than 7F, where a minimum processing dimension is F.

4. The semiconductor integrated circuit of claim 1,
wherein the plurality of nonvolatile memory portions are arranged such that the first and second nonvolatile memories are arranged adjacently in a channel length direction of the first and second nonvolatile memories, and
wherein the first nonvolatile memory and the second nonvolatile memory are sandwiched by the first transistors arranged in a channel width direction of the first and second nonvolatile memories.

5. The semiconductor integrated circuit of claim 1,
wherein a contact connected to the first transistor is provided at a position which is located on the drains of the first and second nonvolatile memories and is interposed between channels of the first and second nonvolatile memories.

6. The semiconductor integrated circuit of claim 5,
wherein the contact is positioned close to the first transistor.

7. The semiconductor integrated circuit of claim 5,
wherein the contact has a width equal to or larger than a channel width of the first nonvolatile memory.

8. The semiconductor integrated circuit of claim 1,
wherein a contact connected to the first transistor is provided at a position which is located on the drains of the first and second nonvolatile memories, but not interposed between channels of the first and second nonvolatile memories.

9. The semiconductor integrated circuit of claim 1,
wherein a length of the control gate of the first nonvolatile memory in a channel length direction thereof is longer than a length of the gate of the first transistor in a channel length direction thereof or a length of the gate of the second transistor in a channel length direction thereof.

10. The semiconductor integrated circuit of claim 1,
wherein a length of the control gate of the first nonvolatile memory in a channel width direction thereof is longer than a length of the gate of the first transistor in a channel width direction thereof or a length of the gate of the second transistor in a channel width direction thereof.

11. The semiconductor integrated circuit of claim 1,
wherein a length of the control gate of the first nonvolatile memory in a channel length direction thereof is shorter than a length of the gate of the first transistor in a channel length direction thereof or a length of the gate of the second transistor in a channel length direction thereof.

12. The semiconductor integrated circuit of claim 1, further comprising:
an element isolation region provided between the adjacent first and second nonvolatile memories,
wherein an angle formed between the element isolation region and the substrate is equal to or more than 90 degrees.

13. The semiconductor integrated circuit of claim 1,
wherein the first nonvolatile memory has a laminated structure in which a first insulating layer is formed above a region between a source and the drain thereof, in which a first charge storage film is formed above the first insulating film, in which a second insulating film is formed above the first charge storage film, and in which a first gate electrode is formed above the second insulating film, and
wherein a film made of a material differing from SiO₂ is formed on the second insulating film.

14. The semiconductor integrated circuit of claim 1,
wherein the first nonvolatile memory has a laminated structure in which a first insulating layer is formed above a region between a source and the drain thereof, in which a first charge storage film is formed above the first insulating film, in which a second insulating film is formed above the first charge storage film, and in which a first gate electrode is formed above the second insulating film,
wherein the second nonvolatile memory has a laminated structure in which a third insulating layer is formed above a region between a source and the drain thereof, in which a second charge storage film is formed above the third insulating film, in which a fourth insulating film is formed above the second charge storage film, and in which a first gate electrode is formed above the fourth insulating film, and
wherein the first charge storage film and the second storage film are separated from each other.

15. The semiconductor integrated circuit of claim 1,
wherein, where each group of the memory transistor areas A1 aligned in a predetermined direction form a row, the rows arranged in a direction perpendicular to the predetermined direction are staggered in the predetermined direction one by one.

16. The semiconductor integrated circuit of claim 1,
wherein, where each group of the memory transistor areas A1 aligned in a predetermined direction form a row, the rows arranged in a direction perpendicular to the predetermined direction are staggered in the predetermined direction two by two.

17. The semiconductor integrated circuit of claim 1,
wherein the substrate include a well, and
wherein the first nonvolatile memory, the a second nonvolatile memory and the first transistor are formed in the well together.

18. The semiconductor integrated circuit of claim 17,
wherein the substrate further include a substrate electrode provided in the well.

19. The semiconductor integrated circuit of claim 1, further comprising:
a wire,
wherein the first transistor and the second transistor form a switch, and
wherein the first and second nonvolatile memories are connected to the wire through the switch.
